(19) United States
(12) Patent Application Publication
(10) Pub. No.: US 2011/0222568 A1
(43) Pub. Date: Sep. 15, 2011

(54) SEMICONDUCTOR LIGHT EMITTING DEVICE

(75) Inventors: Masatoshi SASAKI, Okayama (JP); Toru TAKAYAMA, Hyogo (JP); Atsushi HIGUCHI, Kyoto (JP); Hitoshi SATO, Okayama (JP); Isao KIDOGUCHI, Hyogo (JP)

(73) Assignee: PANASONIC CORPORATION, Osaka (JP)

(21) Appl. No.: 13/046,986

(22) Filed: Mar. 14, 2011

(30) Foreign Application Priority Data
Mar. 15, 2010 (JP) 2010-057967

(51) Int. Cl. H01S 5/343

(52) U.S. Cl. 372/45.01

(57) ABSTRACT

A semiconductor light emitting device includes a first cladding layer 112, an active layer 113, a second cladding layer 114, and a contact layer 117 all of which are formed above a substrate. Between the second cladding layer 114 and the contact layer 117, there is formed a quantum well hetero barrier layer 116 including contact barrier layers 116b and contact well layers 116w. The contact well layers 116w are a first contact well layer 116w formed closer to the contact layer and a second contact well layer 116w3 formed closer to the second cladding layer. E_{CLD2}>E_{CNT} and E_{CW1}<E_{CW2}, when bandgap energy of the second cladding layer 114 is expressed by E_{CLD2}, bandgap energy of the contact layer 117 is expressed by E_{CNT}, bandgap energy of the first contact well layer 116w1 is expressed by E_{CW1}, and bandgap energy of the second contact well layer 116w3 is expressed by E_{CW2}

### BACKGROUND OF THE INVENTION

(1) Field of the Invention

The present invention relates to semiconductor light emitting devices, and more particularly to a semiconductor light emitting device capable of performing high-temperature high-power operations by a low operating voltage.

(2) Description of the Related Art

Semiconductor light emitting devices such as semiconductor lasers and light emitting diodes have been widely used in various fields. Among them, aluminium gallium arsenide (AlGaAs) semiconductor lasers can emit infrared laser light having an emission wavelength band of 780 nm. Furthermore, aluminium gallium indium phosphide (AlGaInP) semiconductor lasers can emit red laser light having an emission wavelength band of 650 nm. These AlGaAs and AlGaInP semiconductor lasers are widely used as light sources in the fields of optical disk systems represented by Compact Discs (CDs) and Digital Versatile Discs (DVDs).

Moreover, with the recent development of enlarged capacity of optical disk systems, Blu-ray Discs (BDs) have appeared on optical disk system market to record a data amount larger than that of CDs and DVDs. For the BD optical disk systems, semiconductor lasers made of nitride such as aluminum gallium indium nitride (AlGaInN) are already used to emit blue-violet laser light having an emission wavelength band of 405 nm.

Under the above circumstances, it has been highly demanded in semiconductor lasers serving as light sources of such optical disk systems to achieve high-power operation by increasing a recording speed, and high-temperature operation at 85° C. or higher. Therefore, high-power semiconductor lasers to serve as light sources of recordable and reproducible optical disk systems are required to perform high-temperature and high-power operations, regardless of the above-described wavelength bands.

In the semiconductor lasers, one of major factors of interfering with high-temperature and high-power operations is an increase of operating voltage. The increase of operating voltage causes an increase of operating power of the element which results in temperature increase caused by joule heat. As a result, an operating current is increased, thereby an operating voltage is increased, and eventually reliability of the element is reduced. Furthermore, a driving circuit for driving the semiconductor laser has an upper limit of a driving voltage. Therefore, suppression of the increase of operating voltage is important in terms of element reliability and in terms of operation control of the driving circuit.

Such increase of operating voltage in the semiconductor lasers is explained by using an example where the laser is an AlGaInP laser emitting red laser light.

In the AlGaInP semiconductor laser, generally, a contact layer is formed on a cladding layer. The cladding layer is made of p-type AlGaInP and formed on one side of an active layer. The contact layer is made of p-type GaAs having bandgap energy smaller than that of the cladding layer. In addition, a metal electrode is formed on the contact layer.

The metal electrode is formed not on the cladding layer but on the contact layer, because bandgap energy of the p-type GaAs contact layer is relatively smaller than bandgap energy of the p-type AlGaInP cladding layer. Therefore, forming of the metal electrode on the p-type GaAs contact layer can reduce a contact resistance between the layer and the metal electrode.

However, in the above situation, on an interface between the p-type AlGaInP cladding layer and the p-type GaAs contact layer, a potential barrier (hetero spike) caused by a difference between bandgap energy of both layers. This potential barrier works as an electrical barrier for holes injected from the metal electrode into the p-type cladding layer. The potential barrier increases an applied voltage required to inject the holes into the p-type cladding layer, thereby increasing an operating voltage.

Therefore, as shown in FIG. 13, a semiconductor laser emitting red laser light generally includes an intermediate layer between the p-type AlGaInP cladding layer and the p-type GaAs contact layer. Here, the intermediate layer is made of p-type GaInP having bandgap energy that is in middle between bandgap energy of the cladding layer and bandgap energy of the contact layer. Thereby, it is possible to split the potential barrier into two pieces and reduce a size of each of the pieces (ΔE_{V1} and ΔE_{V2}). As a result, the increase of an operating voltage can be suppressed.

Here, if AlGaInP material is used for grating matching to GaAs, atomic composition of the material can be expressed by (AlₓGa₁₋ₓ)_{0.51}In_{0.49}P (0≦X≦1). Here, bandgap energy of GaInP having Al composition of 0 is 1.9 eV. In addition, in general, Al composition used as a cladding layer is 0.7, atomic composition of the AlGaInP is (Al_{0.7}Ga_{0.3})_{0.51}In_{0.49}P, and bandgap energy of this AlGaInP is 2.32 eV. Moreover, bandgap energy of GaAs is 1.42 eV.

Therefore, when the p-type GaAs layer forms a junction with the p-type (Al_{0.7}Ga_{0.3})_{0.51}In_{0.49}P layer, a potential barrier of approximately 0.7 eV occurs in the valence band. On the other hand, when the GaAs layer forms a junction with the GaInP layer, the potential barrier (ΔE_{V1}) in the valence band has a size of approximately 0.5 eV as shown in FIG. 13. As explained above, by using an intermediate layer made of p-type GaInP, it is possible to reduce a size of each potential barrier formed in the valence band at a certain degree.

However, even if the potential barrier can be reduced at a certain degree, the potential barrier (ΔE_{V1}) having a size of approximately 0.5 eV remains between the p-type GaInP intermediate layer and the p-type GaAs contact layer, as described earlier.

Therefore, as shown in FIG. 14, the potential barrier (ΔE_{V1}) prevents efficient conduction of holes supplied to the GaAs layer into the GaInP layer, thereby failing to sufficiently suppress the increase of an operating voltage.

In order to solve the above problem, Patent Reference 1 (Japanese Unexamined Patent Application Publication No. 2008-78255) discloses a semiconductor laser device. The following describes the conventional semiconductor layer device disclosed in Patent Reference 1 with reference to FIG. 15. FIG. 15 is a cross-sectional view of the conventional semiconductor laser device.

As shown in FIG. 15, in the conventional semiconductor laser device 500, an intermediate layer 502 made of n-type GaInP, a first N cladding layer 503 made of n-type AlGaInP, and a second N cladding layer 504 made of n-type AlGaInP are sequentially formed on an n-type GaAs substrate 501 (15° off). On the second N cladding layer 504, there are formed a Multiple Quantum Well (MQW) layer 505, a first P cladding layer 506 made of p-type AlGaInP, and an etching stop layer 507 made of p-type GaInP. Here, the MQW layer 505 includes guide layers 505g made of AlGaInP, well layers 505w made of GaInP, and barrier layers 505b made of AlGaInP.

Above the etching stop layer 507, there are a second P cladding layer 508 made of p-type (Al_{0.7}Ga_{0.3})_{0.511}In_{0.489}P, an intermediate layer 509 made of p-type Ga_{0.508}In_{0.492}P, and a cap layer 511 (contact layer) made of p-type GaAs.

Furthermore, in the conventional semiconductor laser device 500, a quantum well hetero barrier layer 510 is formed between the p-type GaInP intermediate layer 509 and the GaAs cap layer 511. The quantum well hetero barrier layer 510 includes three GaAs layers 513a to 513c and three GaInP layers 514.

The three GaAs layers 513a to 513c in the quantum well hetero barrier layer 510, each of which is sandwiched between the GaInP layers 514, have respective different thicknesses. Mentioning from an upper layer, the first GaAs layer 513a has a thickness of 6 nm, the second GaAs layer 513b has a thickness of 4 nm, and the third GaAs layer 513c has a thickness of 2.5 nm. As described above, as the GaAs layers 513a to 513c are getting thinner in a direction from the cap layer 511 to the intermediate layer 509.

Next, operation performed by the conventional semiconductor laser device 500 having the above-described structure is described with reference to FIGS. 16A, 16B, and 17.

FIG. 16A is a graph plotting a relationship between: a thickness of each of the GaAs layers 513a to 513c in the quantum well hetero barrier layer 510; and an energy level and an energy magnitude, in the conventional semiconductor laser device 500. FIG. 16B is a diagram showing energy bands of a GaInP layer and a GaAs layer when a thickness of the GaAs layer is 20 Å or less in FIG. 16A. Note that, in FIG. 16A, the energy represents is a magnitude difference from energy of GaInP valence band end (GaInP valence band end energy).

As shown in FIG. 16A, if the GaAs layers 513a to 513c in the quantum well hetero barrier layer 510 are thinner, a magnitude of a quantized energy level in each GaAs layer serving as a quantum well layer is shifted to higher energy side for holes. Furthermore, if the GaAs layers 513a to 513c are thinner, the number of energy levels in the quantum well hetero barrier layer 510 is further decreased. Here, in FIG. 16A, a curve assigned with a reference HH shows energy of an energy level of a heavy hole, and a curve assigned with a reference LH shows energy of an energy level of a light hole. In addition, curves HH1 and LH1 show energy of a ground state of the heavy hole and energy of a ground state of the light hole, respectively. As a reference numeral is increased, for example from HH2 to HH3, for example, the curve shows energy of a higher-level energy state.

In more detail, as shown in FIG. 16A, if the GaAs layer has a thickness of 25 Å (2.5 nm), it has energy levels of two heavy holes and an energy level of a single light hole. If the GaAs layer has a thickness of 40 Å (4 nm), it has energy levels of three heavy holes and energy levels of two light holes. If the GaAs layer has a thickness of 60 Å (6 nm), it has energy levels of five heavy holes and energy levels of two light holes. Therefore, the quantum well hetero barrier layer 510 made of GaAs/GaInP has total 15 energy levels.

Here, as shown in FIG. 16B, even if the contact well layer is formed to have a thickness of 20 Å or less, there is an energy barrier (ΔE_{Vq}) having energy higher by approximately 0.3 eV than energy of the valence band end of the GaInP intermediate layer.

Next, regarding the conventional semiconductor laser device 500, the following describes valence bands of the second P cladding layer 508 made of p-type AlGaInP, the intermediate layer 509 made of p-type GaInP, the quantum well hetero barrier layer 510 made of GaAs/GaInP, and the cap layer 511 made of p-type GaAs with reference to FIG. 17. FIG. 17 is a diagram showing a valence band in a thermal equilibrium state (zero-bias situation) where a bias voltage is not applied to a structure with junctions among the above layers.

As shown in FIG. 17, when a positive bias voltage is applied to the p-type GaAs cap layer 511, holes supplied from the cap layer 511 are conducted to the GaInP intermediate layer 509 via energy levels in the quantum well hetero barrier layer 510 made of GaAs/GaInP.

Here, the quantum well hetero barrier layer 510 has a plurality of energy levels as shown in FIG. 16 as described above. Therefore, energy of the holes in the cap layer 511 is kept also in the quantum well hetero barrier layer 510. As a result, the holes can easily enter relatively higher energy level. Here, since an energy difference between the higher-level energy level and an energy level of the GaInP intermediate layer 509, the holes can be easily injected into the intermediate layer 509.

More specifically, the holes injected from the cap layer 511 reach the first GaAs layer 513a via the first GaInP layer 514 by tunnel effect, and then reach the third GaAs layer 513c via the second GaInP layer 514, the second GaAs layer 513b, and the third GaInP layer 514. Here, regarding holes residing at a high energy level among holes distributed in the third GaAs layer 513c, a potential barrier for the intermediate layer 509 is small.

Moreover, if a thickness is getting thinner from the first GaAs layer 513a to the third GaAs layer 513c, it is possible to decrease the number of the energy levels in the third GaAs layer 513c, and also to gradually increase an energy magnitude at the same energy level in the third GaAs layer 513c. As a result, in the third GaAs layer 513c, it is possible to increase an existence probability of holes having high energy.

As described above, in the conventional semiconductor laser device 500, the quantum well hetero barrier layer 510 made of GaAs/GaInP is inserted between the intermediate layer 509 made of p-type GaInP and the cap layer 511 made of GaAs. Thereby, the conventional semiconductor laser device 500 can reduce influence of a potential barrier for holes on the interface between the intermediate layer 509 and the cap layer 511. Therefore, holes can be injected by using a low voltage. As a result, an operating voltage of the semiconductor laser device can be decreased.

However, as shown in FIG. 17, in the conventional semiconductor laser device 500, a low energy level still remains in the third GaAs layer 513c and holes exist also at the low energy level.

As a result, there is a problem of failing to efficiently suppress increase of an operating voltage caused by a potential barrier and therefore failing to sufficiently decrease the operating voltage.

### SUMMARY OF THE INVENTION

Thus, the present invention is provided to solve the above problems. An object of the present invention is to provide a semiconductor light emitting device capable of performing high-power operations using a low operating voltage.

In accordance with a first aspect of the present invention for achieving the object, there is provided a semiconductor light emitting device including: a first cladding layer made of a semiconductor layer having a first conductivity type; an active layer; a second cladding layer made of a semiconductor layer having a second conductivity type different from the first conductivity type; and a contact layer made of a semiconductor layer having the second conductivity type, all of which are formed above a semiconductor substrate having the first conductivity type, the semiconductor light emitting device including a quantum well hetero barrier layer including a contact barrier layer having the second conductivity type and contact well layers having the second conductivity type, all of which are formed between the second cladding layer and the contact layer, wherein the contact well layers include at least a first contact well layer and a second contact well layer, the first contact well layer being formed close to the contact layer, and the second contact well layer being formed close to the second cladding layer, and E_{CLD2}>E_{CNT} and E_{CW1}<E_{CW2}, where bandgap energy of the second cladding layer is expressed by E_{CLD2}, bandgap energy of the contact layer is expressed by E_{CNT}, bandgap energy of the first contact well layer is expressed by E_{CW1}, and bandgap energy of the second contact well layer is expressed by E_{CW2}.

With the above structure, it is possible that a magnitude of the highest energy level of the first contact well layer close to the second cladding layer is set to be higher than a magnitude of the highest energy level of the second contact well layer close to the contact layer. As a result, when carriers injected to the second contact well layer are conducted towards the second cladding layer and reach the first contact well layer, potential energy of the carriers is increased. Thereby, it is possible to flow current even in application of a low bias voltage, which decreases an operating voltage.

It is preferable that the bandgap energy of each of the contact well layers is monotonically increased in a the contact layer-to-the second cladding layer direction.

With the above structure, bandgap energy of a plurality of layers included in the quantum well hetero barrier layer is gradually increased (higher) as the layer is closer to the second cladding layer. As a result, it is possible that the number of energy levels of each of the contact well layers is less and a magnitude of the highest energy level of each of the contact well layers is gradually increased (higher), as the layer is closer to the second cladding layer.

Thereby, it is possible that, as a contact well layer is closer to the second cladding layer, an existence probability of holes formed at the highest energy level of the contact well layer is higher and a magnitude of the lowest energy level of the contact well layer is higher. In addition, it is possible that carriers flowing towards the second cladding layer pass the contact barrier layers by tunnel effect, and that, as a contact well layer is closer to the second cladding layer, the carriers existing in the contact well layer exist at a higher energy level.

Therefore, it is possible that, as a contact well layer is closer to the second cladding layer, carriers injected in the contact well layer efficiently and selectively exist at a higher energy level. Therefore, a probability of carriers passing an energy barrier of hetero spike even in application of a low bias voltage is increased. As a result, an operating voltage of the semiconductor light emitting device can be efficiently decreased.

Furthermore, in the first aspect of the semiconductor light emitting device according to the present invention, it is preferable that E_{CLD2}≧E_{CB}>E_{CW2}≧E_{CW1}≧E_{CNT}, where bandgap energy of the contact barrier layer is expressed by E_{CB}.

With the above structure, it is possible to prevent increase of an operating voltage that is caused by hetero spike among the contact barrier layer in the quantum well hetero barrier layer, the second cladding layer, and the contact layer.

It is further preferable in the first aspect of the semiconductor light emitting device according to the present invention that a thickness of each of the contact well layers is monotonically decreased in a contact layer-to-second cladding layer direction.

With the above structure, it is possible that, as a contact well layer is closer to the second cladding layer, an energy level of the contact well layer is gradually increased (higher) and the number of the energy levels is smaller.

With the structure, it is possible that, as a contact well layer is closer to the second cladding layer, the number of carrier existing at the highest energy level of the contact well layer is larger. As a result, the injected carriers can pass hetero spike on an interface between the contact barrier layer and a layer in contact with the contact barrier layer even in application of a lower bias voltage. As a result, an operating voltage of the semiconductor light emitting device can be further decreased.

It is still further preferable in the first aspect of the semiconductor light emitting device according to the present invention that a lattice constant of the contact barrier layer is smaller than a lattice constant of the semiconductor substrate.

With the above structure, extensional strain can be caused in the contact barrier layer. Thereby, it is possible to increase bandgap energy of the contact barrier layer. Thereby, it is possible to increase an energy magnitude at an energy level of the contact well layers. Therefore, the injected carriers can pass hetero spike on an interface between the contact barrier layer and a layer in contact with the contact barrier layer even in application of a lower bias voltage. As a result, an operating voltage of the semiconductor light emitting device can be further decreased.

It is still further preferable in the first aspect of the semiconductor light emitting device according to the present invention that a lattice constant of the contact barrier layer is smaller than a lattice constant of the second cladding layer.

With the above structure, extensional strain can be caused in the contact barrier layer. Thereby, it is possible to increase bandgap energy of the contact barrier layer.

Thereby, it is possible to increase an energy magnitude at an energy level of the contact well layers. As a result, the injected carriers can pass hetero spike on an interface between the contact barrier layer and a layer in contact with the contact barrier layer even in application of a lower bias voltage. As a result, an operating voltage of the semiconductor light emitting device can be further decreased.

In accordance with a second aspect of the present invention for achieving the object, there is provided a semiconductor light emitting device including: a first cladding layer made of AlGaInP material having a first conductivity type; an active layer; a second cladding layer made of AlGaInP material having a second conductivity type different from the first conductivity type; and a contact layer made of GaAs material having the second conductivity type, all of which are formed above a GaAs substrate having the first conductivity type, the semiconductor light emitting device including a quantum well hetero barrier layer including a contact barrier layer and contact well layers, all of which are formed between the second cladding layer and the contact layer, the contact barrier layer being made of (Al_{Xbp}Ga_{1-Xbp})_{Ybp}In_{1-Ybp}P, where 0≦Xbp≦1, and 0<Ybp<1, and the contact well layers each being made of Al_{Xwp}Ga_{1-Xwp}As, where 0≦Xwp<1, wherein the contact well layers include at least a first contact well layer and a second contact well layer, the first contact well layer being formed close to the contact layer, and the second contact well layer being formed close to the second cladding layer, and Xwp1<Xwp2, where Al component of the first contact well layer is expressed by Xwp1 and Al component of the second contact well layer is expressed by Xwp2.

With the above structure, it is possible that, as a contact well layer among the AlGaAs contact well layers in the quantum well hetero barrier layer is closer to the second cladding layer, bandgap energy of the contact well layer is higher. Thereby, it is possible that, as a contact well layer is closer to the second cladding layer, the number of energy levels of the contact well layer is smaller and a magnitude of the highest energy level of the contact well layer is higher.

Thereby, it is possible that an existence probability of holes formed at the highest energy level of the AlGaAs contact well layer that is the closest to the second classing layer is increased, and that a magnitude of the lowest energy level of the contact well layers is also increased. In addition, it is possible that carriers flowing towards the second cladding layer pass the respective AlGInP contact barrier layers by tunnel effect, and that, as a contact well layer is closer to the second cladding layer, the carriers existing in the contact well layer exist at a higher energy level.

Therefore, it is possible that, as a contact well layer is closer to the second cladding layer, carriers injected to the contact well layer efficiently and selectively exist at a higher energy level. Therefore, a probability of carriers passing an energy barrier of hetero spike even in application of a low bias voltage is increased. As a result, an operating voltage of the semiconductor light emitting device can be efficiently decreased.

It is preferable in the second aspect of the semiconductor light emitting device according to the present invention that the Al component Xwp of each of the contact well layers is monotonically increased in a the contact layer-to-the second cladding layer direction.

With the above structure, bandgap energy of a plurality of layers included in the quantum well hetero barrier layer is gradually increased (higher) as the layer is closer to the second cladding layer. As a result, it is possible that the number of energy levels of each of the contact well layers is less and a magnitude of the highest energy level of a contact well layer is gradually increased (higher), as the contact well layer is closer to the second cladding layer.

Therefore, it is possible that, as a contact well layer is closer to the second cladding layer, carriers injected in the contact well layer efficiently and selectively exist at a higher energy level. Thereby, it is possible that a probability of carriers passing an energy barrier of hetero spike even in application of a low bias voltage is increased. As a result, an operating voltage of the semiconductor light emitting device can be efficiently decreased.

It is further preferable in the second aspect of the semiconductor light emitting device according to the present invention that the first contact well layer is the closest to the contact layer among the contact well layers, and has the Al component Xwp1 in a range from 0 to 0.1, and the second contact well layer is the closest to the second cladding layer among the contact well layers, and has the Al component Xwp2 in a range from 0.2 to 0.3.

Since Al component of an AlGaAs contact well layer that is the closest to the GaAs contact layer is in a range from 0 to 0.1, it is possible that the number of energy levels of the AlGaAs contact well layer that is the closest to the GaAs contact layer is increased, and that a tunnel probability of carriers passing from the GaAs contact layer to the AlGaAs contact well layer that is the closest to the GaAs contact layer is increased.

In addition, since Al component of a contact well layer that is the closest to the second cladding layer is in a range from 0.2 to 0.3, it is possible that, if there is a GaInP intermediate layer between the contact barrier layer and the second cladding layer, as a contact well layer is closer to the GaInP intermediate layer, a magnitude of an energy level of the contact well layer approaches a magnitude valence band energy of the GaInP intermediate layer more. Thereby, potential energy of carriers can be efficiently increased. As a result, the carriers can flow into the second cladding layer even in application of a low bias voltage, and an operating voltage of the semiconductor light emitting device can be decreased.

It is further preferable in the second aspect of the semiconductor light emitting device according to the present invention that a thickness of each of the first contact well layer and the second contact well layer is in a range from 20 Å to 60 Å, and a thickness of the contact barrier layer is in a range from 20 Å to 80 Å. With the above structure, an energy level of the contact well layers can be efficiently controlled, and a probability of carriers passing the contact barrier layer by tunnel effect can be increased.

It is still further preferable in the first aspect of the semiconductor light emitting device according to the present invention that a lattice constant of the contact barrier layer is smaller than a lattice constant of the GaAs substrate.

With the above structure, extensional strain can be caused in the AlGaInP contact barrier layer. Thereby, it is possible to increase bandgap energy of the quantum well hetero barrier layer, and increase an energy magnitude of the lowest energy level of each of the contact well layers. Thereby, it is possible to increase potential energy of carriers at the lowest energy level of the contact well layers. As a result, it is possible that a probability of holes passing an energy barrier of hetero spike even in application of a low bias voltage, and that an operating voltage of the semiconductor light emitting device is efficiently further decreased.

In accordance with a third aspect of the present invention for achieving the object, there is provided a semiconductor light emitting device including: a first cladding layer made of AlGaInN material having a first conductivity type; an active layer; a second cladding layer made of AlGaInN material having a second conductivity type different from the first conductivity type; and a contact layer made of GaN material having the second conductivity type, all of which are formed above a GaN substrate having the first conductivity type, the semiconductor light emitting device including a quantum well hetero barrier layer including a contact barrier layer and contact well layers, all of which are formed between the second cladding layer and the contact layer, the contact barrier layer being made of Al_{Xbn}Ga_{Ybn}In_{1-Xbn-Ybn}N, where 0≦Xbn<1, 0<Ybn≦1, and 0≦1−Xbn−Ybn<1, and the contact well layers each being made of Al_{Xwn}Ga_{Ywn}In_{1-Xwn-Ywn}N, where 0≦Xwn<1, 0<Ywn≦1, and 0≦1−Xwn−Ywn<1, wherein the contact well layers include at least a first contact well layer and a second contact well layer, the first contact well layer being formed close to the contact layer, and the second contact well layer being formed close to the second cladding layer, and wherein Xwn1<Xwn2, when Al component of the first contact well layer is expressed by Xwn1 and Al component of the second contact well layer is expressed by Xwn2.

With the above structure, it is possible that, as a contact well layer among the AlGaInN contact well layers in the quantum well hetero barrier layer is closer to the second cladding layer, bandgap energy of the contact well layer is gradually increased (higher). Thereby, it is possible that, as a contact well layer is closer to the second cladding layer, the number of energy levels of the contact well layer is smaller and a magnitude of the highest energy level of the contact well layer is gradually increased (higher).

Thereby, it is possible that an existence probability of holes formed at the highest energy level of the AlGaInN contact well layer that is the closest to the second classing layer is increased, and that a magnitude of the lowest energy level of the contact well layers is also increased. In addition, it is possible that carriers flowing towards the second cladding layer pass the respective AlGaInN contact barrier layers by tunnel effect, and that, as a contact well layer is closer to the second cladding layer, the carriers existing in the contact well layer exist at a higher energy level.

Therefore, it is possible that, as a contact well layer is closer to the second cladding layer, carriers injected to the contact well layer efficiently and selectively exist at a higher energy level. Therefore, a probability of carriers passing an energy barrier of hetero spike even in application of a low bias voltage is increased. As a result, an operating voltage of the semiconductor light emitting device can be efficiently decreased.

It is preferable in the third aspect of the semiconductor light emitting device according to the present invention that the bandgap energy of each of the contact well layers is monotonically increased in a contact layer-to-second cladding layer direction.

With the above structure, bandgap energy of a plurality of layers included in the quantum well hetero barrier layer is gradually increased (higher) as the layer is closer to the second cladding layer. As a result, it is possible that, as a contact well layer is closer to the second cladding layer, the number of energy levels of the contact well layer is smaller and a magnitude of the highest energy level of the contact well layer is gradually increased (higher).

Therefore, it is possible that, as a contact well layer is closer to the second cladding layer, carriers injected to the contact well layer efficiently and selectively exist at a higher energy level. Therefore, a probability of carriers passing an energy barrier of hetero spike even in application of a low bias voltage is increased. As a result, an operating voltage of the semiconductor light emitting device can be efficiently decreased.

It is further preferable in the third aspect of the semiconductor light emitting device according to the present invention that the first contact well layer is the closest to the contact layer among the contact well layers, and has the Al component Xwn1 in a range from 0 to 0.05, and the second contact well layer is the closest to the second cladding layer among the contact well layers, and has the Al component Xwn2 that is equal to or less than Al component of the second cladding layer.

With the above structure, it is possible that the number of energy levels of the AlGaInP contact well layer that is the closest to the GaN contact layer is increased, and that a tunnel probability of carriers passing from the GaN contact layer to the AlGaInP contact well layer that is the closest to the GaN contact layer is increased.

In addition, since Al component of a contact well layer that is the closest to the second cladding layer is equal or less than Al component of the second cladding layer, it is possible that, as a contact well layer is closer to the AlGaN cladding layer, a magnitude of an energy level of the contact well layer approach more to a magnitude of valence band energy of the AlGaN cladding layer. Thereby, it is possible to efficiently increase potential energy of carriers. As a result, carriers can flow into the cladding layer even in application of a low bias voltage, and an operating voltage of the semiconductor light emitting device can be decreased.

It is still further preferable in the third aspect of the semiconductor light emitting device according to the present invention that a thickness of each of the first contact well layer and the second contact well layer is in a range from 20 Å to 60 Å, and a thickness of the contact barrier layer is in a range from 20 Å to 80 Å.

With the above structure, energy levels of the contact well layers can be efficiently controlled, and a probability of carriers passing the contact barrier layer by tunnel effect can be increased.

It is still further preferable in the third aspect of the semiconductor light emitting device according to the present invention that a lattice constant of the contact barrier layer is smaller than a lattice constant of the GaN substrate.

With the above structure, extensional strain can be caused in the contact barrier layer. Thereby, it is possible to increase bandgap energy of the contact barrier layer. Thereby, it is possible to increase an energy magnitude at an energy level of the contact well layers. Therefore, the injected carriers can pass hetero spike on an interface between the contact barrier layer and a layer in contact with the contact barrier layer even in application of a lower bias voltage. As a result, an operating voltage of the semiconductor light emitting device can be further decreased.

As described above, according to the semiconductor light emitting device according to the present invention, it is possible that bandgap energy of the contact well layers in the quantum well hetero barrier layer is gradually increased (higher), as the contact well layer is closer to the second cladding layer. Thereby, it is possible that, as a contact well layer is closer to the second cladding layer, the number of energy levels of the contact well layer is smaller and a magnitude of the highest energy level of the contact well layer is higher.

Thereby, it is possible that, as a contact well layer is closer to the second cladding layer, an existence probability of carriers existing at the highest energy level of the contact well layer is higher, and a magnitude of the lowest energy level of the contact well layer is also higher.

Therefore, it is possible that injected carriers efficiently and selectively exist at a high energy level. As a result, a probability of holes passing an energy barrier of hetero spike even in application of a low bias voltage can be increased, which efficiently increases an operating voltage.

Thereby, a semiconductor light emitting device capable of operating in application of a low operating voltage can be achieved.

Further Information about Technical Background to this Application

The disclosure of Japanese Patent Application No. 2010-057967 filed on Mar. 15, 2010 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1A is a cross-sectional view of a semiconductor laser device according to a first embodiment of the present invention;

FIG. 1B is an enlarged cross-sectional view of a main region A in the semiconductor laser device in FIG. 1A according to the first embodiment of the present invention;

FIG. 1C is an enlarged cross-sectional view of a main region B in the semiconductor laser device in FIG. 1A according to the first embodiment of the present invention;

FIG. 2 is a graph plotting a relationship between: Al composition of an AlGaAs contact well layer (40 Å); and an energy level and an energy magnitude of holes formed in the contact well layer;

FIG. 3 is a graph plotting a relationship between: Al composition of an AlGaAs contact well layer (20 Å); and an energy level and an energy magnitude of holes formed in the contact well layer;

FIG. 4 is a diagram showing a valence band in the situation where an intermediate layer, a quantum well hetero barrier layer, and a contact layer form a junction with each other in a zero-bias situation in the semiconductor laser device according to the first embodiment of the present invention;

FIG. 5A is a graph plotting current-voltage characteristics of the semiconductor laser device according to the first embodiment of the present invention;

FIG. 5B is a graph plotting current-light output characteristics of the semiconductor laser device according to the first embodiment of the present invention;

FIG. 6 is a diagram showing a valence band in the situation where an intermediate layer, a quantum well hetero barrier layer, and a contact layer form a junction with each other in a zero-bias situation in a semiconductor laser device according to a variation of the first embodiment;

FIG. 7A is a cross-sectional view of a semiconductor laser device according to a second embodiment of the present invention;

FIG. 7B is an enlarged cross-sectional view of a main region C in the semiconductor laser device in FIG. 7A according to the second embodiment of the present invention;

FIG. 7C is an enlarged cross-sectional view of a main region D in the semiconductor laser device in FIG. 7A according to the second embodiment of the present invention;

FIG. 8A is a cross-sectional view of a semiconductor laser device according to a third embodiment of the present invention;

FIG. 8B is an enlarged cross-sectional view of a main region E in the semiconductor laser device in FIG. 8A according to the third embodiment of the present invention;

FIG. 9 is a graph plotting a relationship between: Al composition of an AlGaN contact well layer (40 Å); and an energy level and an energy magnitude of holes formed in the contact well layer;

FIG. 10 is a graph plotting a relationship between: Al composition of an AlGaN contact well layer (20 Å); and an energy level and an energy magnitude of holes formed in the contact well layer;

FIG. 11 is a graph plotting a relationship between: Al composition of an AlGaN contact well layer (40 Å); and an energy level and an energy magnitude of holes formed in the contact well layer;

FIG. 12 is a graph plotting a relationship between: Al composition of an AlGaN contact well layer (20 Å); and an energy level and an energy magnitude of holes formed in the contact well layer;

FIG. 13 is a graph showing a band in forming junctions among a p-type AlGaInP layer, a p-type GaInP layer, and a p-type GaAs layer;

FIG. 14 is a graph showing a valence band in forming a junction between a p-type GaInP layer and a p-type GaAs layer;

FIG. 15 is a cross-sectional view of a conventional semiconductor laser device;

FIG. 16A is a graph plotting a relationship between: a thickness of a GaAs layer in a quantum well hetero barrier layer; and an energy level and an energy magnitude, in the conventional semiconductor laser device;

FIG. 16B is a diagram showing energy bands of a GaInP layer and a GaAs layer; and

FIG. 17 is a diagram showing a valence band in the situation where a second cladding layer, an intermediate layer, a quantum well hetero barrier layer, and a cap layer form junctions with each other in a zero-bias situation in the conventional semiconductor laser device.

### DESCRIPTION OF THE PREFERRED EMBODIMENT(S)

The following describes the semiconductor light emitting device according to embodiments of the present invention with reference to the drawings. In the following embodiments, a semiconductor laser device is described as an aspect of the semiconductor light emitting device.

### First Embodiment

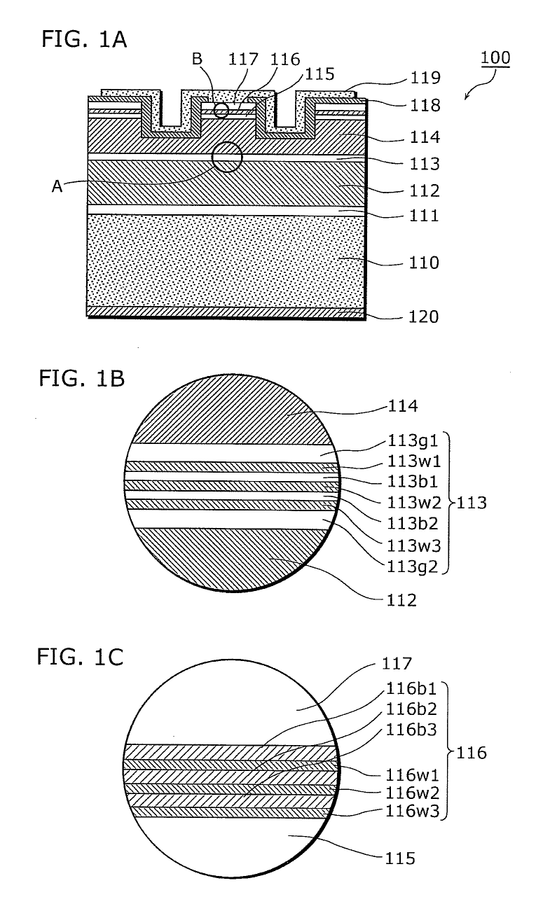

First, a semiconductor laser device according to the first embodiment of the present invention is described with reference to FIGS. 1A to 1C. FIG. 1A is a cross-sectional view of the semiconductor laser device according to the first embodiment of the present invention. FIG. 1B is an enlarged cross-sectional view of a main region A in the semiconductor laser device in FIG. 1A according to the first embodiment of the present invention. FIG. 1C is an enlarged cross-sectional view of a main region B in the semiconductor laser device in FIG. 1A according to the first embodiment of the present invention.

As shown in FIG. 1A, the semiconductor laser device 100 according to the first embodiment of the present invention is an AlGaInP semiconductor laser device for emitting red laser light. The semiconductor laser device 100 includes an n-type GaAs substrate 110 having a main surface inclining by 10 degrees in a [011] direction from a (100) plane. On the GaAs substrate 110, the semiconductor laser device 100 includes: a buffer layer 111 made of n-type GaAs with a thickness of 0.2 μm; a first cladding layer 112 made of n-type (Al_{X2}Ga_{1-X2})_{0.51}In_{0.49}P with a thickness of 2.0 μm; an active layer 113 having a strained quantum well structure; a second cladding layer 114 made of p-type (Al_{X1}Ga_{1-X1})_{0.51}In_{0.49}P; an intermediate layer 115 made of p-type Ga_{0.51}In_{0.49}P with a thickness of 500 Å; a p-type quantum well hetero barrier layer 116; and a contact layer 117 made of p-type GaAs with a thickness of 0.4 μm.

Furthermore, as shown in FIG. 1B, the active layer 113 includes two light guide layers, three well layers, and two barrier layers. More specifically, on the first cladding layer 112, there are sequentially stacked a second light guide layer 113g2, a third well layer 113w3, a second barrier layer 113b2, a second well layer 113w2, a first barrier layer 113b1, a first well layer 113w1, and a first light guide layer 113g1.

Here, each of the first light guide layer 113g1 and the second light guide layer 113g2 is made of (Al_{0.5}Ga_{0.5})_{0.51}In_{0.49}P and has a thickness of 200 Å. Each of the first well layer 113w1, the second well layer 113w2, and the third well layer 113w3 is made of GaInP. Each of the first barrier layer 113b1 and the second barrier layer 113b2 is made of (Al_{0.5}Ga_{0.5})_{0.51}In_{0.49}P.

As shown in FIG. 1A, in the semiconductor laser device 100 according to the first embodiment, ridge parts are also formed, and a current block layer 118 made of dielectric substance SiN with a thickness of 0.7 μm is formed to cover side surfaces of the ridge parts. Moreover, a p-type ohmic electrode 119 having a multilayer structure of Ti/Pt/Au is formed to be in contact with an opening part of the contact layer 117 and to cover the current block layer 118. In addition, an n-type ohmic electrode 120 having a multilayer structure of AuGe/Ni/Au is formed to be in contact with the GaAs substrate 110.

In the first embodiment, the second cladding layer 114 is formed so that a distance between an upper portion of a ridge part of the second cladding layer 114 and the active layer 113 is 1.4 μm and a distance dp between a lower end portion of the ridge part of the second cladding layer 114 and the active layer 113 is 0.2 μm. Each of Al composition X1 of the first cladding layer 112 and Al composition X2 of the second cladding layer 114 is 0.7 to have the highest bandgap energy, in order to prevent carriers injected into the active layer 113 from overflowing due to heat.

In the semiconductor laser device 100 according to the first embodiment, when current is injected into the contact layer 117 via the ohmic electrode 119, the current flowing from the contact layer 117 is narrowed only at the ridge part by the current block layer 118, and thereby flows cocentratedly to a portion of the active layer 113 which is below a bottom of the ridge part.

Thereby, a small amount of injected current of approximately tens of mA can cause inverted population of carriers required for laser emission. Here, light emitted by recombination of the carriers injected into the active layer 113 is changed to high-power laser emission by optical confinement effect. More specifically, in a direction perpendicular to the active layer 113, vertical optical confinement is performed by the first cladding layer 112 and the second cladding layer 114, while, in a direction parallel to the active layer 113, horizontal optical confinement is performed because the current block layer 118 has a refractive index lower than that of the second cladding layer 114. Moreover, since the current block layer 118 is transparent to laser emission light and therefore does not absorb light, forming of the current block layer 118 can realize a low-loss optical waveguide. In addition, light distribution of laser light propagated in the optical waveguide can significantly exude to the current block layer 118. It is therefore possible to easily achieve a refractive index difference (Δn) of 10⁻³ order that is suitable for high-power operations. Furthermore, a value of the refractive index difference can be controlled with high accuracy of the same 10⁻³ order depending on the distance dp between the lower end portion of the ridge part of the second cladding layer 114 and the active layer 113. Therefore, a high-power semiconductor laser operated by a low operating voltage can be achieved while light distribution is controlled with high accuracy.

Meanwhile, when a semiconductor laser device is used as a light source for a recording/reproducing device of an optical disk system, the light distribution of the semiconductor laser needs to produce fundamental transverse mode emission operations in order to collect laser emission light onto an optical disk.

In order to produce stable fundamental transverse mode emission even in a high-temperature high-power state, it is necessary to decide a structure of a waveguide to cut off higher-level transverse mode emission. Therefore, it is necessary not only to control the above-described Δn with high accuracy of 10⁻³ order, but also to narrow a width of the bottom of the ridge part to cut off the higher-level transverse mode emission. In order to suppress the higher-level transverse mode emission, the width of the bottom of the ridge part should be narrowed to 3 μm or less.

However, such a narrow width of the bottom of the ridge part causes a narrow width of the upper portion of the ridge part depending on a mesa shape of the ridge part. A too narrow width of the upper portion of the ridge part causes a narrow width of the current path along which current flows from the upper portion of the ridge part to the device, which results in increase of series resistance (Rs) of the device and eventually in increase of an operating voltage.

Therefore, it a width of the bottom of the ridge part is merely narrowed to produce stable fundamental transverse mode emission, an operating voltage is increased which results in heat. As a result, high-temperature and high-power operations are difficult.

Therefore, in order to perform operations by a low operating voltage, the semiconductor laser device 100 according to the first embodiment of the present invention includes the quantum well hetero barrier layer 116 between the intermediate layer 115 and the contact layer 117.

As shown in FIG. 1C, the quantum well hetero barrier layer 116 according to the first embodiment has a plurality of contact barrier layers 116b each made of p-type (Al_{Xbp}Ga_{1-Xbp})_{Ybp}In_{1-Ybp}P (where 0≦Xbp≦1, and 0<Ybp<1), and a plurality of contact well layers 116w each made of p-type Al_{Xwp}Ga_{1-Xwp}As (where 0≦Xwp 1).

The plurality of contact barrier layers 116b are a first contact barrier layer 116b1, a second contact barrier layer 116b2, and a third contact barrier layer 116b3. The plurality of contact well layers 116w are a first contact well layer 116w1, a second contact well layer 116w2, and a third contact well layer 116w3.

Regarding the layers in the quantum well hetero barrier layer 116, on the intermediate layer 115, there are sequentially stacked the third contact well layer 116w3, the third contact barrier layer 116b3, the second contact well layer 116w2, the second contact barrier layer 116b2, the first contact well layer 116w1, and the first contact barrier layer 116b1.

In the first embodiment, Al components Xwp1 to Xwp3 of the first contact well layer 116w1 to the third contact well layer 116w3 satisfy Xwp1<Xwp2<Xwp3. Furthermore, Al component Xwp in each contact well layer 116w is monotonically increased in a contact layer 117-to-intermediate layer 115 direction, in other words, in an order from a layer closer to the contact layer 117 to a layer closer to the intermediate layer 115 (close to the second cladding layer 114). Here, each of the first contact well layer 116w1 to the third contact well layer 116w3 has a thickness of 40 Å.

Furthermore, each of the first contact barrier layer 116b1 to the third contact barrier layer 116b3 has Xbp=0 and Ybp=0.51 and is made of Ga_{0.51}In_{0.49}P, so as to have the same composition ratio as that of the intermediate layer 115. Each of the first contact barrier layer 116b1 to the third contact barrier layer 116b3 has a thickness of 60 Å.

Next, description is given for operation of the quantum well hetero barrier layer 116 in the semiconductor laser device 110 according to the first embodiment of the present invention. First, Al component of each contact well layer 116w is described.

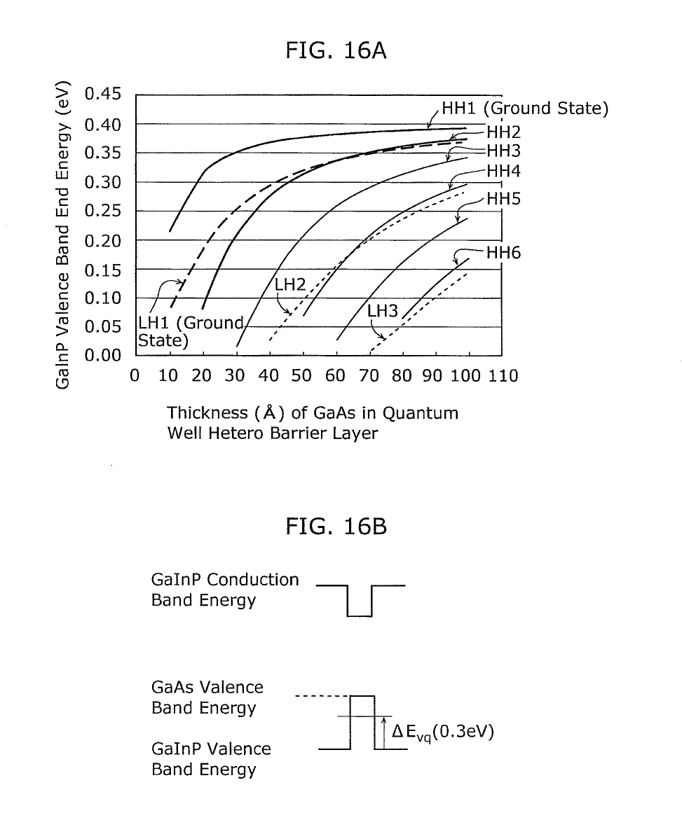

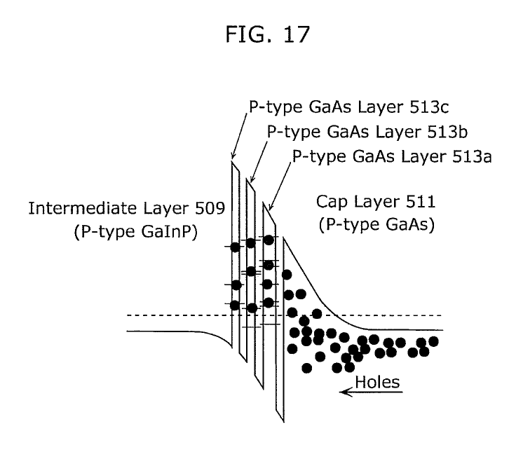

Here, for example, material of every contact well layer 116w included in the quantum well hetero barrier layer 116 is assumed to be GaAs, like the conventional semiconductor laser device. In the above structure, as shown in FIG. 16A, even if each contact well layer is formed thin having a thickness of 20 Å or less, an energy level for holes formed in a valence band is increased to be higher by approximately 0.1 eV than a valence band end energy of the contact well layer. Therefore, as shown in FIG. 16B, there is an energy barrier (ΔE_{Vq}) having energy higher by approximately 0.3 eV than the valence band end energy of the GaInP intermediate layer.

Therefore, in the above structure, even if three GaAs contact well layers are gradually thinner from 60 Å to 20 Å as being closer to the intermediate layer 115, like the conventional semiconductor laser device 500, a magnitude of the lowest energy of an energy level for holes is increased by approximately 0.1 eV at most. Thereby, even if the contact well layer 116w in contact with the intermediate layer 115 is capable of having (a) an energy level of holes causing the highest energy and (b) an energy level of holes for which a size of a hetero barrier is reduced so that an energy magnitude is higher by 0.15 eV than the valence band end of the GaInP intermediate layer 115, there are still holes at the energy level in the ground state. As a result, it is impossible to efficiently reduce a size of the hetero barrier for all holes between the contact layer 117 and the intermediate layer 115.

Therefore, in the semiconductor laser device 100 according to the first embodiment of the present invention, the first contact well layer 116w1 to the third contact well layer 116w3 which are included in the quantum well hetero barrier layer 116 are made of AlGaAs, Al components Xwp1 to Xwp3 satisfy Xwp1 <Xwp2<Xwp3, and each Al component Xwp is monotonically increased in an order from a layer closer to the contact layer 117 to a layer closer to the intermediate layer 115 (close to the second cladding layer 114) as described above. In addition, the contact barrier layer 116b is made of GaInP. Thereby, regarding the first contact well layer 116w1 to the third contact well layer 116w3, bandgap energy is higher as the layer is closer to the GaInP intermediate layer 115.

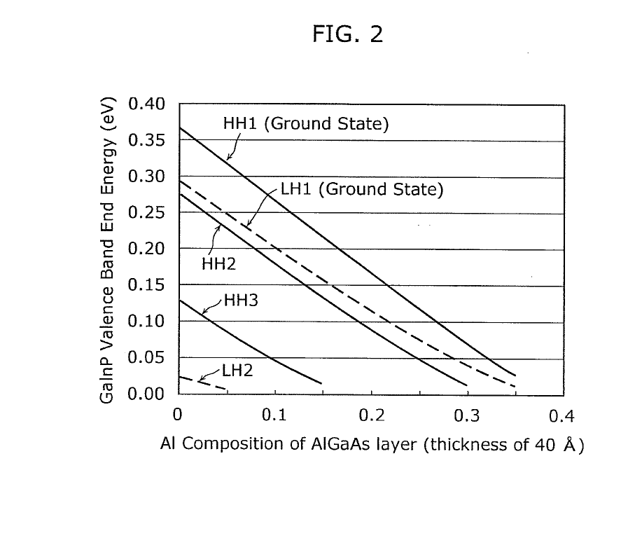

Here, description is given for a relationship between: Al composition of a contact well layer 116w; and an energy level and an energy magnitude of holes formed in the contact well layer 116w with reference to FIG. 2. FIG. 2 is a graph plotting a relationship between: Al composition of an AlGaAs contact well layer 116w (having a thickness of 40 Å); and an energy level and an energy magnitude of holes formed in the contact well layer 116w. In FIG. 2, the contact well layer 116w has a thickness of 40 Å to obtain quantum effect. Al composition of the contact well layer 116w varies from 0 to 0.35. In FIG. 2, the energy is a magnitude difference from GaInP valence band end energy. A curve assigned with a reference HH shows energy of an energy level of a heavy hole, and a curve assigned with a reference LH shows energy of an energy level of a light hole. In addition, curves HH1 and LH1 show energy of a ground state of the heavy hole and energy of a ground state of the light hole, respectively. As a reference numeral is increased, for example from HH2 to HH3, for example, the curve shows energy of a higher-level energy state. Regarding HH and LH, the same goes for the subsequent embodiments.

As shown in FIG. 2, as Al component of the contact well layer 116w is increased, an energy level of a ground state of holes formed in the contact well layer 116w approaches the GaInP valence band end energy. In addition, as shown in FIG. 2, in the case of Al component of 0.35, a magnitude of the GaInP valence band end energy and a magnitude of energy in the contact well layer 116w are substantially equal.

Furthermore, as shown in FIG. 2, as Al component of the contact well layer 116w is increased, the number of energy levels in the contact well layer 116w is decreased.

As seen above, if Al component of a contact well layer that is the closest to the contact layer 117 is the least and Al component of a contact well layer that is closer to the intermediate layer 115 is larger, it is possible to efficiently further approach energy of holes in the contact well layers 116w towards the GaInP valence band end energy as the holes are conducted in the contact well layers 116w.

Especially, it is preferable in the first embodiment that Al component of the first contact well layer 116w1, which is a contact well layer the closest to the contact layer 117, is set in a range from 0 to 0.1. With the above structure, as shown in FIG. 2, it is possible to approach the energy level of holes in a ground state which are formed in the first contact well layer 116w1 towards the GaInP valence band end energy to be higher by approximately 0.1 eV than the GaInP valence band end energy. In the above situation, holes injected from the contact layer 117 are injected into the first contact well layer 116w1 by tunnel effect without being blocked by a large hetero barrier.

It is further preferable in the first embodiment that Al component of the third contact well layer 116w3, which is a contact well layer the closest to the intermediate layer 115, is set in a range from 0.2 to 0.3. It is thereby possible, as shown in FIG. 2, to set a size of the hetero barrier, which blocks holes passing from the third contact well layer 116w3 to the intermediate layer 115, to be approximately 0.15 eV or less. With the above structure, holes in the third contact well layer 116w3 are injected to the intermediate layer 115 without being blocked by a large hetero barrier.

In the first embodiment as described above, the contact well layer 116w includes three layers which are the first contact well layer 116w1 to the third contact well layer 116w3, Al components Xwp1 to Xwp3 of the respective layers satisfy Xwp1=0.05, Xwp2=0.15, and Xwp3=0.25, and Al component is gradually increased as the layer is closer to the intermediate layer 115.

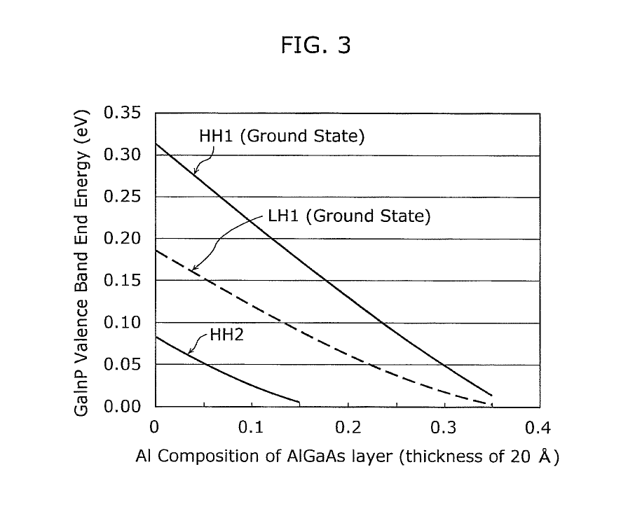

As described above, the case where the contact well layer 116w has a thickness of 40 Å has been described. Next, the case where the contact well layer 116w has a thickness of 20 Å is described with reference to FIG. 3. FIG. 3 is a graph plotting a relationship between: Al composition of an AlGaAs contact well layer (having a thickness of 20 Å); and an energy level and an energy magnitude of holes formed in the contact well layer. FIG. 3 differs from FIG. 2 in a thickness of the contact well layer 116w. Also in FIG. 3, the energy represents a magnitude difference from GaInP valence band end energy.

In comparing FIG. 3 to FIG. 2, as the contact well layer 116w is thinner, the number of energy levels of holes formed in the contact well layer 116w is decreased in the case of the same Al component. For example, when the contact well layer 116w has Al component of 0.05, as shown in FIG. 3, the number of energy levels of holes is three in the case of the thickness of 20 Å. Therefore, the number of energy levels in FIG. 3 is smaller than the number of energy levels in the case of a thickness of 40 Å shown in FIG. 2. Therefore, as the contact well layer 116w is thinner, a probability of holes passing the contact barrier layer 116b by tunnel effect is decreased. On the contrary, as the contact well layer 116w is thicker, the probability of holes passing the contact barrier layer 116b by tunnel effect is increased.

However, if the contact well layer 116w is too thick, the number of energy levels of holes formed in the contact well layer 116w is too many, which decreases the probability of holes in high energy state. In other words, a probability of holes existing at an energy level the closet to the GaInP valence band end energy is decreased.

Meanwhile, on an interface between the contact well layer 116w and the contact barrier layer 116b, interface layers sometimes form mixed crystal. In such a case, average Al component of the contact well layer 116w is further increased, thereby decreasing the number of energy levels.

Therefore, it is preferable to form each contact well layer 116w to have a thickness in a range from 20 Å to 60 Å. In the first embodiment, each contact well layer 116w has a thickness of 40 Å.

Next, description is given for a relationship between electric conduction of the contact barrier layer 116b and a thickness of the contact barrier layer 116b.

When a bias voltage is applied to the semiconductor laser device 100 to supply current to the semiconductor laser device 100, holes injected from the contact layer 117 first passes the contact well layer 116w1 via the contact barrier layer 116b1. Here, it is necessary to make the contact barrier layer 116b1 thin to enable the holes to pass the contact barrier layer 116b1 by tunnel effect. Thereby, even if there is a hetero barrier on an interface between the contact barrier layer 116b1 and the contact layer 117, the holes can reach the contact well layer 116w1 even in application of a low bias voltage.

In order to produce the tunnel effect, each of the first contact barrier layer 116b1 to the third contact barrier layer 116b3 should be thin having a thickness equal to or less than approximately a wavelength of a wave function of the holes, namely, 80 Å or less.

On the contrary, if the first contact barrier layer 116b1 to the third contact barrier layer 116b3 are too thin, combination of quantum levels between the contact well layers is firm to form miniband.

In the above situation, the energy levels of holes formed in each of the contact well layer 116w1 to 116w3 are split. Thereby, a probability of holes existing in a low energy state in the contact well layers is increased. Therefore, when holes are conducted from the third contact well layer 116w3 to the intermediate layer 115, a ratio of holes blocked by a large hetero barrier is still increased. As a result, an effect of decreasing an operating voltage is reduced.

Therefore, in order to keep a high tunnel probability and to prevent miniband from being forming caused by combination of quantum levels of holes between the contact well layers, it is preferable that each contact barrier layer 116b has a thickness in a range from 20 Å to 80 Å. In the first embodiment, each contact barrier layer 116b has a thickness of 60 Å.

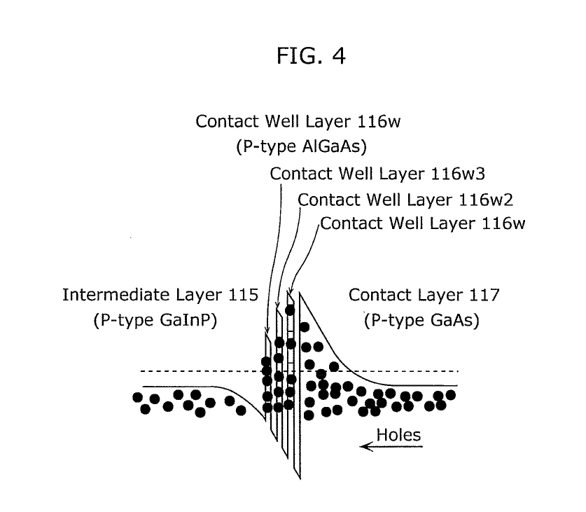

Next, regarding the semiconductor laser device 100 according to the first embodiment of the present invention, description is given for a valence band in the situation where the intermediate layer 115, the quantum well hetero barrier layer 116, and the contact layer 117 form a junction with each other. FIG. 4 is a diagram showing a valence band in the situation where the intermediate layer, the quantum well hetero barrier layer, and the contact layer form a junction with each other in a zero-bias situation in the semiconductor laser device 100 according to the first embodiment of the present invention.

In the first embodiment, it is assumed that the second cladding layer 114 is made of (Al_{0.7}Ga_{0.3})_{0.51}In_{0.49}P, that the intermediate layer 115 is made of Ga_{0.51}In_{0.49}P, and that the contact layer 117 is made of GaAs.

It is also assumed that, regarding Al components Xwp1 to Xwp3 of the respective first contact well layer 116w1 to the third contact well layer 116w3, Xwp1=0.05, Xwp2=0.15, and Xwp3=0.25, as described above. More specifically, the first contact well layer 116w1 closer to the contact layer 117 is made of Al_{0.05}Ga_{0.95}As, the second contact well layer 116w2 in the middle of the contact well layers is made of Al_{0.15}Ga_{0.85}As, and the third contact well layer 116w3 closer to the intermediate layer 115 is made of Al_{0.25}Ga_{0.75}As.

In the semiconductor laser device 100 according to the first embodiment as described above, when bandgap energies of the second cladding layer 114, the contact layer 117, the first contact well layer 116w1, the second contact well layer 116w2, and the third contact well layer 116w3 are expressed as E_{CLD2}, E_{CNT}, E_{CM}, E_{CW2}, and E_{CW3}, it is satisfied that E_{CLD2}>E_{CNT} and E_{CW1}<E_{CW2}<E_{CW3}.

Moreover, each of the first contact barrier layer 116b1 to the third contact barrier layer 116b3 has a thickness of 60 Å and is made of Ga_{0.51}In_{0.49}P where Al component Xbp=0 and Ga component Ybp=0.51

With the above structure, the number of energy levels of holes formed in the first contact barrier layer 116b1 that is the closest to the contact layer 117 is five. Thereby, the energy levels can be increased. As a result, a ratio of holes passing from the contact layer 117 to the contact barrier layer 116b1 by tunnel effect can be increased.

Here, E_{CLD2}≧E_{CB}>E_{CW3}>E_{CW2}>E_{CW1}≧E_{CNT}, when bandgap energy of each of the first contact barrier layer 116b1 to the third contact barrier layer 116b3 is E_{CB}.

In the semiconductor laser device 100 according to the first embodiment of the present invention having the above-described structure, as shown in FIG. 4, as holes are conducted in the quantum well hetero barrier layer 116 by tunnel effect, the holes can be effectively conducted from the first contact well layer 116w1 eventually to the third contact well layer 116w3 via high energy levels. In this case, an energy magnitude of the GaInP valence band end energy is decreased to be lower by 0.05 eV than the highest energy level of the holes formed in the third contact well layer 116w3. Therefore, even in application of a low bias voltage, the holes can be conducted from the contact layer 117 to the intermediate layer 115.

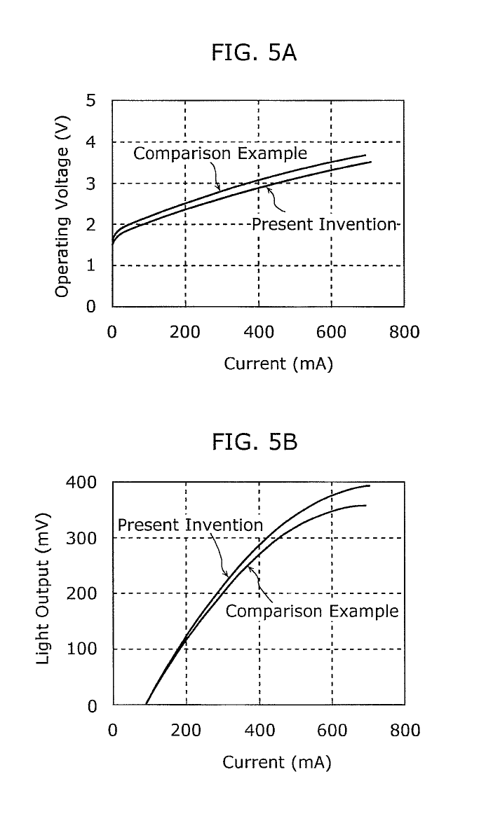

Next, description is given for current-voltage characteristics and current-light output characteristics in the semiconductor laser device 100 according to the first embodiment of the present invention with reference to FIGS. 5A and 5B. FIG. 5A is a graph plotting current-voltage characteristics of the semiconductor laser device according to the first embodiment of the present invention. FIG. 5B is a graph plotting current-light output characteristics of the semiconductor laser device according to the first embodiment of the present invention. Here, FIG. 5B shows current-light output characteristics in high-temperature pulse driving with 85° C., 50 ns, and a duty of 50%. In FIGS. 5A and 5B, “Present Invention” shows a characteristic curve regarding the semiconductor laser device 100 according to the first embodiment which includes the quantum well hetero barrier layer 116, while “Comparison Example” shows a characteristic curve regarding a semiconductor laser device without the quantum well hetero barrier layer 116.

As shown in FIG. 5A, the semiconductor laser device 100 according to the first embodiment which includes the quantum well hetero barrier layer 116 is capable of steadily decreasing an operating voltage to be lower by approximately 0.2 V than an operation voltage of the comparison example that is the semiconductor laser device without the quantum well hetero barrier layer 116.

Furthermore, it is observed from FIG. 5B that the semiconductor laser device 100 according to the first embodiment which includes the quantum well hetero barrier layer 116 can improve thermal saturation to be lower by approximately 50 mW than thermal saturation of the comparison example that is the semiconductor laser device without the quantum well hetero barrier layer 116.

### Variation of First Embodiment

The following describes a semiconductor laser device according to a variation of the first embodiment.

In the semiconductor laser device 100 according to the first embodiment described above, the plurality of contact well layers 116w have the identical thicknesses. In the semiconductor laser device according to the variation, however, the contact well layers 116w have different thicknesses.

More specifically, in the semiconductor laser device according to the variation, Al components in the contact well layers 116w are gradually increased in an order from a layer closer to the contact layer 117 to a layer closer to the intermediate layer 115. In addition, the contact well layers 116w are gradually thinner in an order from a layer closer to the contact layer 117 to a layer closer to the intermediate layer 115. Other structure of the semiconductor laser device according to the variation is same as that of the semiconductor laser device 100 according to the first embodiment described above.

In more detail, the first contact well layer 116w1 which is the closest to the contact layer 117 has a thickness of 60 Å and Al component of 0.05. The second contact well layer 116w2 has a thickness of 40 Å and Al component of 0.15. The third contact well layer 116w3, which is the closet to the intermediate layer 115, has a thickness of 20 Å and Al component of 0.25.

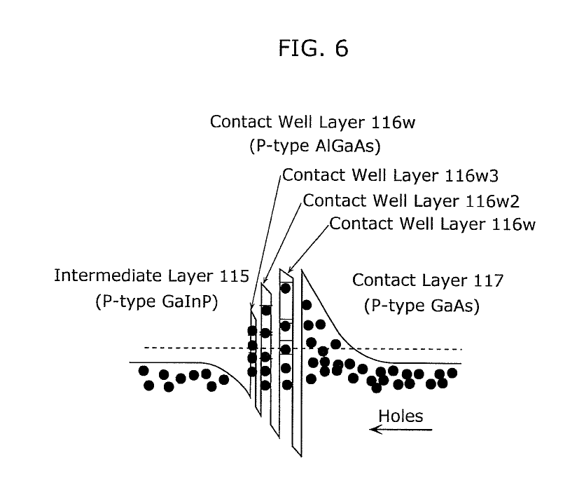

FIG. 6 is a diagram showing a valence band in the situation where the intermediate layer, the quantum well hetero barrier layer, and the contact layer form a junction with each other in a zero-bias situation in the semiconductor laser device according to the variation of the first embodiment.

As shown in FIG. 6, the semiconductor laser device according to the variation can approach energy of holes in the contact well layer 116w towards the GaInP valence band end energy as the contact well layer is closer to the intermediate layer 115. In addition, the semiconductor laser device according to the variation can decrease the number of energy levels of holes.

As a result, it is possible to efficiently have holes injected from the contact layer 117 to exist at an energy level that is the most closest to the GaInP valence band end energy in the third contact well layer 116w3. Thereby, it is possible to achieve an operating voltage lower than that in the semiconductor laser device 100 according to the first embodiment.

### Second Embodiment

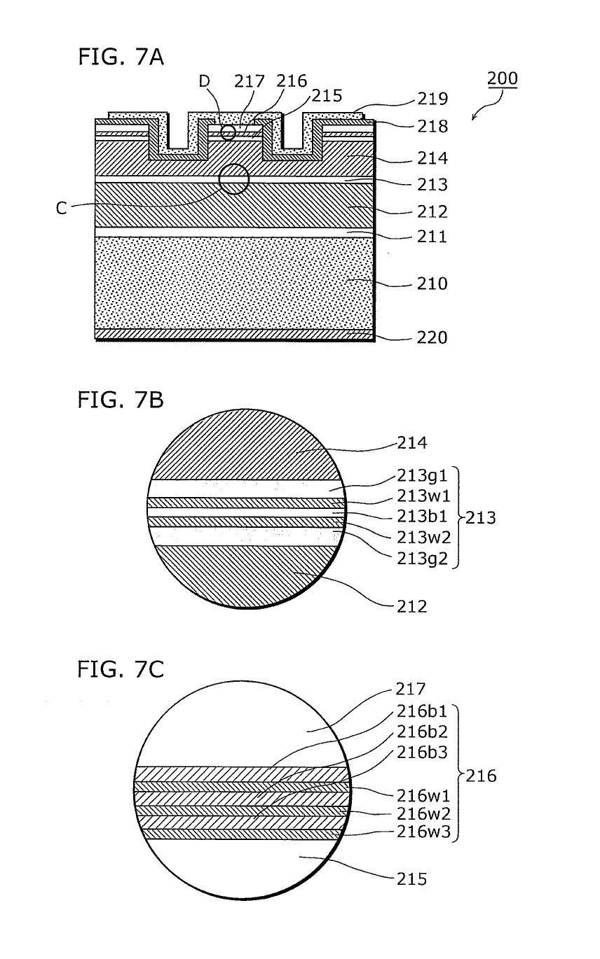

Next, a semiconductor laser device according to the second embodiment of the present invention is described with reference to FIGS. 7A to 7C. FIG. 7A is a cross-sectional view of the semiconductor laser device according to the second embodiment of the present invention. FIG. 7B is an enlarged cross-sectional view of a main region C in the semiconductor laser device in FIG. 7A according to the second embodiment of the present invention. FIG. 7C is an enlarged cross-sectional view of a main region D in the semiconductor laser device in FIG. 7A according to the second embodiment of the present invention.

As shown in FIG. 7A, the semiconductor laser device 200 according to the second embodiment of the present invention is an AlGaAs semiconductor laser device for emitting infrared laser light. The semiconductor laser device 200 includes an n-type GaAs substrate 210. On the GaAs substrate 210, the semiconductor laser device 200 includes: a buffer layer 211 made of n-type GaAs with a thickness of 0.5 μm; a first cladding layer 212 made of n-type (Al_{X4}Ga_{1-X4})_{0.51}In_{0.49}P with a thickness of 2.0 μm; an active layer 213 having a quantum well structure; a second cladding layer 214 made of p-type (Al_{X3}Ga_{1-X3})_{0.51}In_{0.49}P; an intermediate layer 215 made of p-type Ga_{0.51}In_{0.49}P with a thickness of 500 Å; a p-type quantum well hetero barrier layer 216; and a contact layer 217 made of p-type GaAs with a thickness of 0.4 μm.

Furthermore, as shown in FIG. 7B, the active layer 213 includes a first light guide layer 213g1, a second light guide layer 213g2, a first well layer 213w1, a second well layer 213w2, and a first barrier layer 213b1. On the first cladding layer 212, these layers are sequentially stacked in an order of the second light guide layer 213g2, the second well layer 213w2, the first barrier layer 213b1, the first well layer 213w1, and the first light guide layer 213g1.

Here, each of the first light guide layer 213g1 and the second light guide layer 213g2 is made of Al_{0.5}Ga_{0.5}As and has a thickness of 200 Å. Each of the first well layer 213w1 and the second well layer 213w2 is made of GaAs. The first barrier layer 213b1 is made of Al_{0.5}Ga_{0.5}As.

Like in the semiconductor laser device 100 according to the first embodiment, also in the semiconductor laser device 200 according to the second embodiment, ridge parts are also formed, and a current block layer 218 made of dielectric substance SiN with a thickness of 0.7 μm is formed to cover side surfaces of the ridge parts. Moreover, a p-type ohmic electrode 219 having a multilayer structure of Ti/Pt/Au is formed to be in contact with an opening part of the contact layer 217 and to cover the current block layer 218. In addition, an n-type ohmic electrode 220 having a multilayer structure of AuGe/Ni/Au is formed to be in contact with the GaAs substrate 210.

In the second embodiment, the second cladding layer 214 is formed so that a distance between an upper portion of the ridge part of the second cladding layer 214 and the active layer 213 is 1.4 μm and a distance dp between a lower end portion of the ridge part of the second cladding layer 214 and the active layer 213 is 0.24 μm.

Each of Al composition X3 of the first cladding layer and Al composition X2 of the second cladding layer is 0.7 to have the highest bandgap energy, in order to prevent carriers injected into the active layer 213 from overflowing due to heat.

Furthermore, in the second embodiment, since the active layer 213 is made of AlGaAs material, and the first cladding layer 212 and the second cladding layer 214 are made of AlGaInP material, the difference between bandgap energy of the active layer and bandgap energy of the cladding layer is increased. As a result, it is possible to further prevent carriers injected into the active layer 213 from overflowing due to heat.

In the semiconductor laser device 200 having the above-described structure according to the second embodiment, when current is injected into the contact layer 217 via the ohmic electrode 219, the current flowing from the contact layer 217 is narrowed only at the ridge part by the current block layer 218, and thereby flows concentratedly to a portion of the active layer 213 which is below a bottom of the ridge part.

Thereby, a small amount of injected current of approximately tens of mA can cause inverted population of carriers required for laser emission. Here, light emitted by recombination of the carriers injected into the active layer 213 is changed to high-power laser emission by optical confinement effect. More specifically, in a direction perpendicular to the active layer 213, vertical optical confinement is performed by the first cladding layer 212 and the second cladding layer 214, while, in a direction parallel to the active layer 213, horizontal optical confinement is performed because the current block layer 218 has a refractive index lower than that of the second cladding layer 214. Moreover, since the current block layer 218 is transparent to laser emission light and therefore does not absorb light, forming of the current block layer 218 can realize a low-loss optical waveguide. In addition, light distribution of laser light propagated in the optical waveguide can be significantly exuded to the current block layer 218. It is therefore possible to easily achieve a refractive index difference (an) of 10⁻³ order that is suitable for high-power operations. Furthermore, a value of the refractive index difference can be controlled with high accuracy of the same 10⁻³ order depending on the distance dp between the lower end portion of the ridge part of the second cladding layer 214 and the active layer 213. Therefore, a high-power semiconductor laser operated by a low operating voltage can be achieved while light distribution is controlled with high accuracy.

Meanwhile, like the first embodiment, when the semiconductor laser device 200 according to the second embodiment is used as a light source for recording/reproducing operations of an optical disk system, the light distribution of the semiconductor laser needs to produce fundamental transverse mode emission operations in order to collect laser emission light onto an optical disk.

In order to produce stable fundamental transverse mode emission even in a high-temperature high-power state, it is necessary to decide a structure of a waveguide to cut off higher-level transverse mode emission. Therefore, it is necessary not only to control the above-described Δn with high accuracy of 10⁻³ order, but also to narrow a width of the bottom of the ridge part to cut off the higher-level transverse mode emission. In order to suppress the higher-level transverse mode emission, the width of the bottom of the ridge part should be narrowed to 4 μm or less.

However, such a narrow width of the bottom of the ridge part causes a narrow width of the upper portion of the ridge part depending on a mesa shape of the ridge part. A too narrow width of the upper portion of the ridge part causes a narrow width of the current path along which current flows from the upper portion of the ridge part to the device, which results in increase of series resistance (RS) of the device and eventually in increase of an operating voltage.

Therefore, it a width of the bottom of the ridge part is merely narrowed to produce stable fundamental transverse mode emission, an operating voltage is increased which results in heat. As a result, high-temperature and high-power operations are difficult.

Therefore, in order to perform operations by a low operating voltage, the semiconductor laser device 200 according to the second embodiment of the present invention includes a quantum well hetero barrier layer 216 between the intermediate layer 215 and the contact layer 217.

As shown in FIG. 7C, the quantum well hetero barrier layer 216 according to the second embodiment has a plurality of contact barrier layers 216b each made of p-type GaInP and a plurality of contact well layers 216w each made of p-type AlGaAs.

The plurality of contact barrier layers 216b are a first contact barrier layer 216b1, a second contact barrier layer 216b2, and a third contact barrier layer 216b3. The plurality of contact well layers 216w are a first contact well layer 216w1, a second contact well layer 216w2, and a third contact well layer 216w3.

Regarding the layers in the quantum well hetero barrier layer 216, on the intermediate layer 215, there are sequentially stacked the third contact well layer 216w3, the third contact barrier layer 216b3, the second contact well layer 216w2, the second contact barrier layer 216b2, the first contact well layer 216w1, and the first contact barrier layer 216b1.

In the second embodiment, Al components in the first contact well layer 216w1 to the third contact well layer 216w3 are monotonically increased in a contact layer 217-to-intermediate layer 215 direction, in other words, in an order from a layer closer to the contact layer 217 to a layer closer to the intermediate layer 215 (close to the second cladding layer 214).

Each of the first contact well layer 216w1 to the third contact well layer 216w3 has a thickness of 40 Å to obtain quantum effect. Like the first embodiment, Al compositions of the contact well layers 116w are gradually increased to be 0.05, 0.15, and 0.25, respectively, as the layer is closer to the intermediate layer 215.

With the above structure, it is possible to efficiently approach energy of holes in the contact well layers 216w towards the GaInP valence band end energy as the holes are conducted in the contact well layers 216w towards the intermediate layer 215. Therefore, an operating voltage can be decreased even in an infrared laser device including an AlGaAs active layer and an AlGaInP cladding layer.

### Third Embodiment

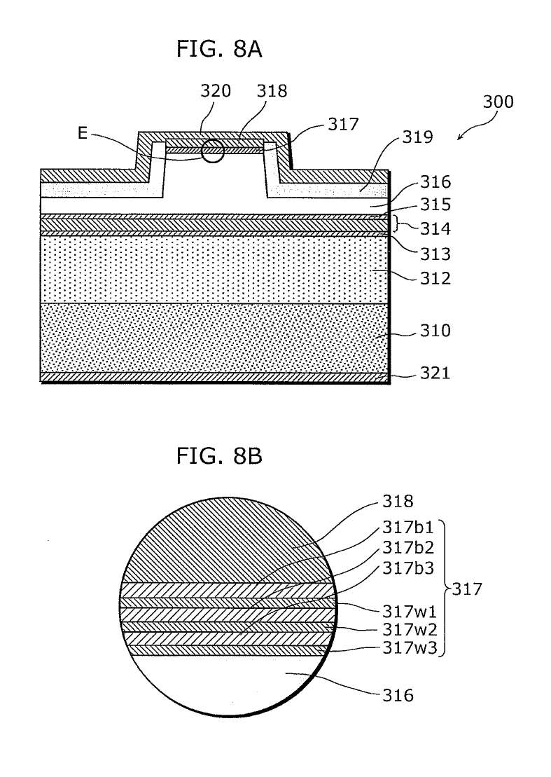

Next, a semiconductor laser device according to the third embodiment of the present invention is described with reference to FIGS. 8A and 8B. FIG. 8A is a cross-sectional view of the semiconductor laser device according to the third embodiment of the present invention. FIG. 8B is an enlarged cross-sectional view of a main region E in the semiconductor laser device in FIG. 8A according to the third embodiment of the present invention.

As shown in FIG. 8A, the semiconductor laser device 300 according to the third embodiment of the present invention is a semiconductor laser device made of nitride material to emit blue-violet laser light. The semiconductor laser device 300 includes a GaN substrate 310. On the GaN substrate 310, the semiconductor laser device 300 includes: a first cladding layer 312 made of n-type AlGaN with a thickness of 2.5 μm; a first guide layer 313 made of n-type AlGaN with a thickness of 860 Å; an active layer 314 having a quantum well structure made of InGaN; an electron block layer 315 made of p-type AlGaN with a thickness of 100 Å; a second cladding layer 316 made of p-type AlGaN; a p-type quantum well hetero barrier layer 317; and a contact layer 318 made of p-type GaN with a thickness of 0.1 μm.

In addition, in the semiconductor laser device 300 according to the third embodiment, ridge parts are also formed, and a current block layer 319 made of dielectric substance SiN with a thickness of 0.1 μm is formed to cover side surfaces of the ridge parts. Moreover, a p-type ohmic electrode 320 having a multilayer structure of Pd/Pt/Ti/Au is formed to be in contact with an opening part of the contact layer 318 and to cover the current block layer 319. In addition, an n-type ohmic electrode 321 having a multilayer structure of Ti/Pt/Au is formed to be in contact with the GaN substrate 310. In the third embodiment, a width of each of the ridge parts is 1.4 μm.

In the third embodiment, the second cladding layer 316 is formed so that a distance between an upper portion of the ridge part of the second cladding layer 316 and the active layer 314 is 0.5 μm and a distance dp between a lower end portion of the ridge part of the second cladding layer 316 and the active layer 314 is 0.1 μm.

Al component of the second cladding layer is 0.1 in order to prevent carriers injected into the active layer 314 from overflowing due to heat.

Moreover, in the third embodiment, when Al components of the first cladding layer 312 and the second cladding layer 316 are increased, it is possible to increase a difference between bandgap energy of the active layer and bandgap energy of the cladding layer. Thereby, it is possible to further prevent carriers injected to the active layer 314 from overflowing due to heat. However, a difference between a coefficient of thermal expansion of the AlGaN layer and a coefficient of thermal expansion of the GaN substrate causes lattice defect when Al component of the AlGaN cladding layer is too many. As a result, reliability is reduced. Therefore, Al component of the cladding layer is preferably 0.2 or less in manufacturing the device.

In the semiconductor laser device 300 having the above-described structure according to the third embodiment, when current is injected into the contact layer 318 via the ohmic electrode 320, the current flowing from the contact layer 318 is narrowed only at the ridge part by the current block layer 319, and thereby flows concentratedly to a portion of the active layer 314 which is below a bottom of the ridge part.

Thereby, a small amount of injected current of approximately tens of mA can cause inverted population of carriers required for laser emission. Here, light emitted by recombination of the carriers injected into the active layer 314 is changed to high-power laser emission by optical confinement effect. More specifically, in a direction perpendicular to the active layer 314, vertical optical confinement is performed by the first cladding layer 312 and the second cladding layer 316, while, in a direction parallel to the active layer 314, horizontal optical confinement is performed because the current block layer 319 has a refractive index lower than that of the second cladding layer 316. Moreover, since the current block layer 319 is transparent to laser emission light and therefore does not absorb light, forming of the current block layer 319 can realize a low-loss optical waveguide. In addition, light distribution of laser light propagated in the optical waveguide can significantly exude to the current block layer 319. It is therefore possible to easily achieve a refractive index difference (Δn) of 10⁻³ order that is suitable for high-power operations. Furthermore, a value of the refractive index difference can be controlled with high accuracy of the same 10⁻³ order depending on the distance dp between the lower end portion of the ridge part of the second cladding layer 316 and the active layer 314. Therefore, a high-power semiconductor laser operated by a low operating voltage can be achieved while light distribution is controlled with high accuracy.

Meanwhile, like the first and second embodiments, when the semiconductor laser device 300 according to the third embodiment is used as a light source for recording/reproducing operations of an optical disk system, the light distribution of the semiconductor laser needs to produce fundamental transverse mode emission operations in order to collect laser emission light onto an optical disk.

In order to produce stable fundamental transverse mode emission even in a high-temperature high-power state, it is necessary to decide a structure of a waveguide to cut off higher-level transverse mode emission. Therefore, it is necessary not only to control the above-described Δn with high accuracy of 10⁻³ order, but also to narrow a width of the bottom of the ridge part to cut off the higher-level transverse mode emission. In order to suppress the higher-level transverse mode emission, the width of the bottom of the ridge part should be narrowed to 1.5 μm or less.

However, such a narrow width of the bottom of the ridge part causes a narrow width of the upper portion of the ridge part depending on a mesa shape of the ridge part. A too narrow width of the upper portion of the ridge part causes a narrow width of the current path along which current flows from the upper portion of the ridge part to the device, which results in increase of series resistance (Rs) of the device and eventually in increase of an operating voltage.

Therefore, it a width of the bottom of the ridge part is merely narrowed to produce stable fundamental transverse mode emission, an operating voltage is increased which results in heat. As a result, high-temperature and high-power operations are difficult.

Therefore, in order to perform operations by a low operating voltage, the semiconductor laser device 300 according to the third embodiment of the present invention includes the quantum well hetero barrier layer 317 between the intermediate layer 316 and the contact layer 318.

As shown in FIG. 8B, the quantum well hetero barrier layer 317 according to the third embodiment has a plurality of contact barrier layers 317b each made of p-type Al_{Xbn}Ga_{Ybn}In_{1-Xbn-Ybn}N (where 0≦Xbn<1, 0<Ybn≦1, and 0≦1−Xbn−Ybn<1), and a plurality of contact well layers 317w each made of p-type Al_{Xwn}Ga_{Ywn}In_{1-Xwn-Ywn}N (where 0≦Xwn<1, 0<Ywn≦1, and 0≦1−Xwn−Ywn<1).

The plurality of contact barrier layers 317b are a first contact barrier layer 317b1, a second contact barrier layer 317b2, and a third contact barrier layer 317b3. The plurality of contact well layers 317w are a first contact well layer 317w1, a second contact well layer 317w2, and a third contact well layer 317w3.

Regarding the layers in the quantum well hetero barrier layer 317, on the second cladding layer 316, there are sequentially stacked the third contact well layer 317w3, the third contact barrier layer 317b3, the second contact well layer 317w2, the second contact barrier layer 317b2, the first contact well layer 317w1, and the first contact barrier layer 317b1.

In the third embodiment, Al components Xwn1 to Xwn3 of the first contact well layer 317w1 to the third contact well layer 317w3 satisfy Xwn1<Xwn2<Xwn3. In other words, Al component Xwn in each contact well layer 317w is monotonically increased in a contact layer 318-to-second cladding layer 316 direction, in other words, in an order from a layer closer to the contact layer 318 to a layer closer to the second cladding layer 316.

Furthermore, each of the first contact barrier layer 317b1 to the third contact barrier layer 317b3 has Xbn=0.1 and Ybn=0.9 and is made of Al_{0.1}Ga_{0.9}N, so as to have the same composition ratio as that of the second cladding layer 316.

Next, description is given for operation of the quantum well hetero barrier layer 317 in the semiconductor laser device 300 according to the third embodiment of the present invention.

In a structure that does not include the quantum well hetero barrier layer 317, if Al component of the second cladding layer 316 made of p-type AlGaN is 0.1, there is formed a hetero barrier having energy of 0.07 eV for holes on an interface between the second cladding layer 316 and the contact layer 318 made of p-type GaN. If the Al component of the second cladding layer 316 is 0.2, there is formed a hetero barrier having energy of 0.14 eV for holes on the interface between the second cladding layer 316 and the contact layer 318.

The hetero barrier increases not only a rising voltage in current-voltage characteristics, but also series resistance (Rs) of the device which eventually increases an operating voltage. Since the nitride semiconductor laser as described in the third embodiment has high bandgap energy due to characteristics of the material, an operating voltage is originally high. Therefore, it is very important for the nitride semiconductor laser as described in the third embodiment to decrease the operating voltage.

Therefore, as described above, in the semiconductor laser device 300 according to the third embodiment of the present invention, between the second cladding layer 316 made of p-type AlGaN and the contact layer 318 made of GaN there is the quantum well hetero barrier layer 317 which includes the contact well layers 317w.

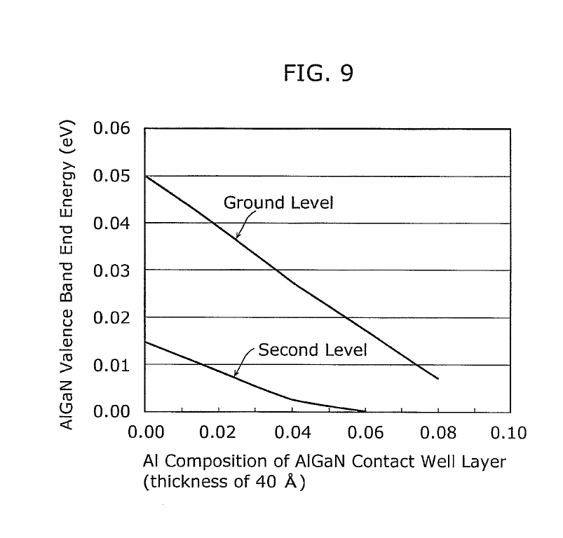

The following describes a relationship between Al component and a thickness regarding the contact well layers 317w and the contact barrier layers 317b in the quantum well hetero barrier layer 317, and the contact layer 318 in detail with reference to FIGS. 9 to 12.

FIG. 9 is a graph plotting a relationship between: Al composition of the AlGaN contact well layer 317w having a thickness of 40 Å; and an energy level and an energy magnitude of holes formed in the contact well layer 317w.

Here, in FIG. 9, the second cladding layer 316 is made of AlGaN having Al component of 0.1, each of the first contact barrier layer 317b1 to the third contact barrier layer 317b3 are made of AlGaN having Al component of 0.1, and each of the first contact well layer 317w1 to the third contact well layer 317w3 are made of AlGaN having a thickness of 40 Å. With the structure, Al component of each of the first contact well layer 317w1 to the third contact well layer 317w3 is varied from 0 to 0.08. In FIG. 9, the energy represents a difference from quantum level energy of a valence band end of AlGaN contact barrier layer.

As shown in FIG. 9, Al component of the AlGaN contact well layer 317w is increased to be 0.025, 0.05, and then 0.75 in order to approach the Al component towards Al component (0.1) of the second cladding layer 316. In this case, an energy level of holes formed in the contact well layer is expressed by energy from the valence band end of the second cladding layer 316. Thereby, it is possible to sequentially approach an energy level of holes in a ground state to be 0.024 eV, 0.013 eV, and then 0.005 eV at small approximately 0.01 eV intervals.

As a result, an energy level of holes injected from the contact layer 318 towards the second cladding layer 316 is efficiently increased as a layer between the contact layer 318 and the second cladding layer 316 is closer to the second cladding layer 316. Thereby, the injected holes efficiently reach the second cladding layer 316 via the quantum well hetero barrier layer 317. As a result, it is possible to prevent increase of an operating voltage.

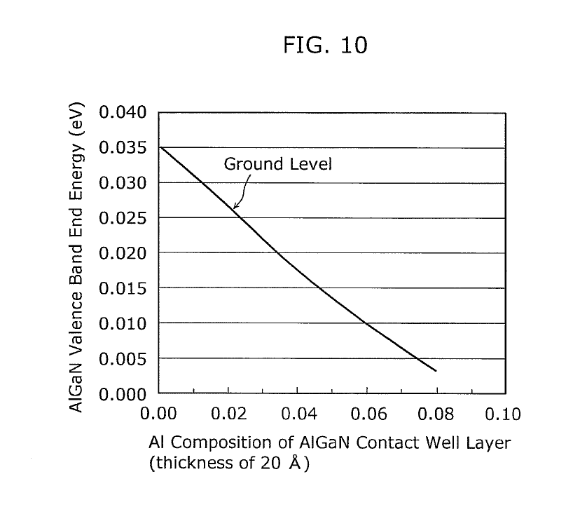

FIG. 10 is a graph plotting a relationship between: Al composition of the AlGaN contact well layer 317w having a thickness of 20 Å; and an energy level and an energy magnitude of holes formed in the contact well layer 317w. Here, conditions in FIG. 10 differs from those in FIG. 9 only in a thickness of each of the first contact well layer 317w1 to the third contact well layer 317w3.

As shown in FIG. 10, Al component of the AlGaN contact well layer 317w is increased to be 0.025, 0.05, and then 0.75 in order to approach the Al component towards Al component (0.1) of the second cladding layer 316. In this case, an energy level of holes formed in the contact well layer is expressed by energy from the valence band end of the second cladding layer 316. Thereby, it is possible to sequentially approach an energy level of holes in a ground state to be 0.037 eV, 0.025 eV, and then 0.01 eV at small approximate 0.01 eV intervals.

As a result, like FIG. 9 described above, an energy level of holes injected from the contact layer 318 towards the second cladding layer 316 is efficiently increased as a layer between the contact layer 318 and the second cladding layer 316 is closer to the second cladding layer 316. Thereby, the injected holes efficiently reach the second cladding layer 316 via the quantum well hetero barrier layer 317. As a result, it is possible to prevent increase of an operating voltage.

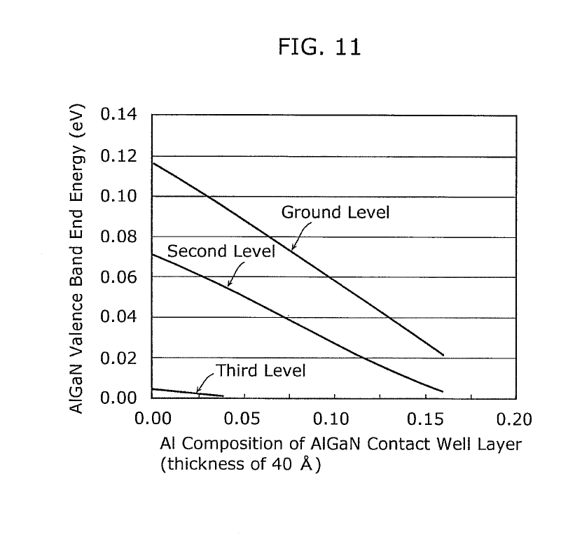

FIG. 11 is a graph plotting a relationship between: Al composition of the AlGaN contact well layer 317w having a thickness of 40 Å; and an energy level and an energy magnitude of holes formed in the contact well layer 317w.

Here, in FIG. 11, the second cladding layer 316 is made of AlGaN having Al component of 0.1, each of the first contact barrier layer 317b1 to the third contact barrier layer 317b3 are made of AlGaN having Al component of 0.2, and each of the first contact well layer 317w1 to the third contact well layer 317w3 are made of AlGaN having a thickness of 40 Å. With the structure, Al component of each of the first contact well layer 317w1 to the third contact well layer 317w3 is varied from 0 to 0.16. In FIG. 11, the energy represents a difference from quantum level energy of a valence band end of AlGaN contact barrier layer.

As shown in FIG. 11, Al component of the AlGaN contact well layer 317w is increased to be 0.05, 0.1, and then 0.15 in order to approach the Al component towards Al component (0.2) of the second cladding layer 316. In this case, an energy level of holes formed in the contact well layer is expressed by energy from the valence band end of the second cladding layer 316. Thereby, it is possible to sequentially approach an energy level of holes in a ground state to be 0.088 eV, 0.056 eV, and then 0.028 eV at small approximate 0.03 eV intervals.

As a result, an energy level of holes injected from the contact layer 318 towards the second cladding layer 316 is efficiently increased as a layer between the contact layer 318 and the second cladding layer 316 is closer to the second cladding layer 316. Thereby, the injected holes efficiently reach the second cladding layer 316 via the quantum well hetero barrier layer 317. As a result, it is possible to prevent increase of an operating voltage.

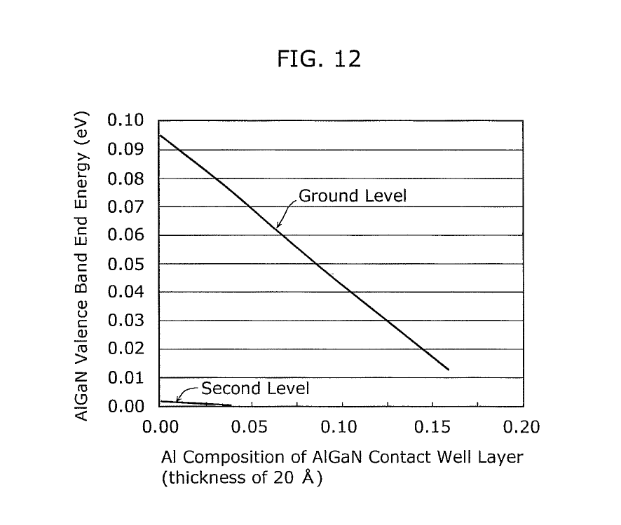

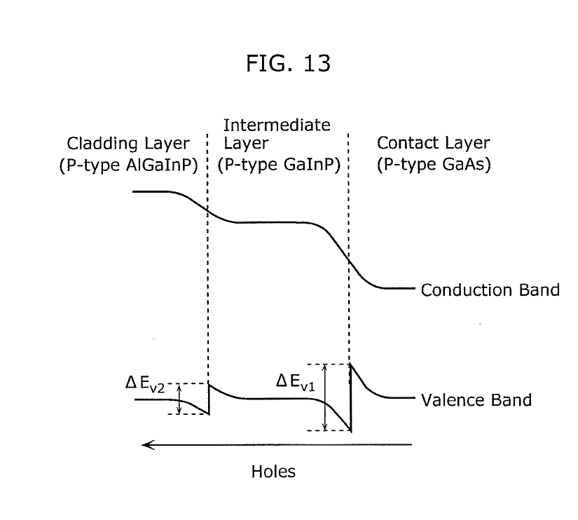

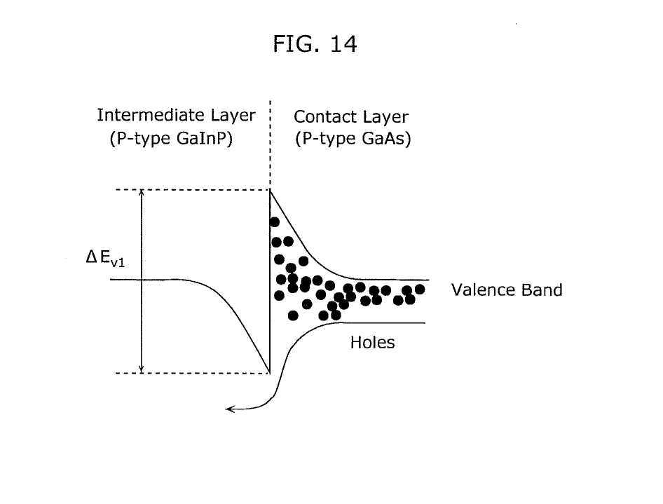

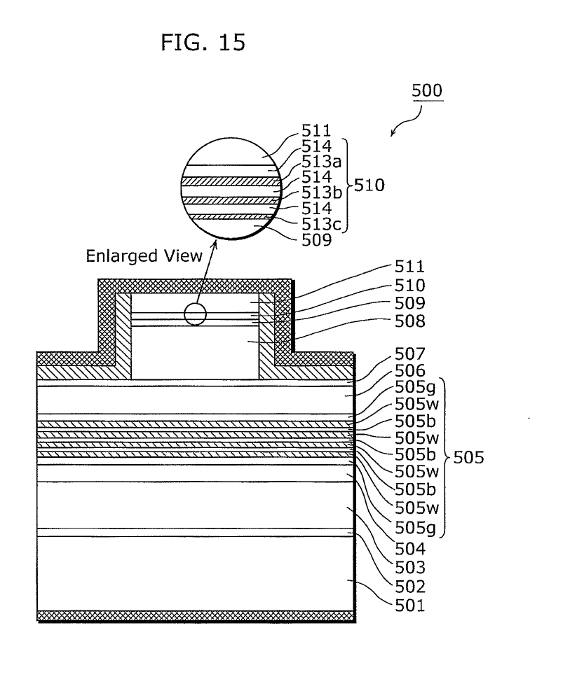

FIG. 12 is a graph plotting a relationship between: Al composition of the AlGaN contact well layer 317w having a thickness of 20 Å; and an energy level and an energy magnitude of holes formed in the contact well layer 317w. Here, conditions in FIG. 12 differ from conditions in FIG. 11 only in a thickness of each of the first contact well layer 317w1 to the third contact well layer 317w3.

As shown in FIG. 12, Al component of the AlGaN contact well layer 317w is increased to be 0.05, 0.1, and then 0.15 in order to approach the Al component towards Al component (0.2) of the second cladding layer 316. In this case, an energy level of holes formed in the contact well layer is expressed by energy from the valence band end of the second cladding layer 316. Thereby, it is possible to sequentially approach an energy level of holes in a ground state to be 0.07 eV, 0.043 eV, and then 0.018 eV at small approximate 0.03 eV intervals.

As a result, like FIG. 11 described above, an energy level of holes injected from the contact layer 318 towards the second cladding layer 316 is efficiently increased as a layer between the contact layer 318 and the second cladding layer 316 is closer to the second cladding layer 316. Thereby, the injected holes efficiently reach the second cladding layer 316 via the quantum well hetero barrier layer 317. As a result, it is possible to prevent increase of an operating voltage.

It should be noted regarding Al components of the contact well layers 317w that Al component of the first contact well layer 317w1 that is the closest to the contact layer 318 is preferably in a range from 0 to 0.05. Thereby, it is possible to approach an energy level of holes in a ground state which are formed in the first contact well layer 317w1 towards energy of holes in a p-type GaN valence band. As a result, a probability of holes passing the first contact barrier layer 317b1 by tunnel effect is increased, which further decreases an operating voltage.

It is further preferable that Al components of each contact well layer 317w is equal to or less than Al component of the second cladding layer 316. Thereby, it is possible to prevent that energy of holes formed in the contact well layers 317w is higher than required.

Regarding a thickness of each contact well layer 317w, as seen in FIGS. 9 to 12, if a contact well layer 317w is thin, the number of energy levels of holes formed in the contact well layer 317w is decreased. Therefore, as the contact well layer 317w is thinner, a probability of holes passing the contact barrier layer 317b by tunnel effect is decreased. On the contrary, as the contact well layer 317w is thicker, the probability of holes passing the contact barrier layer 317b by tunnel effect is increased.

However, if the contact well layer 317w is too thick, the number of energy levels of holes formed in the contact well layer 317w is too many, which decreases the probability of holes in high energy state. In other words, a probability of holes existing at an energy level the closet to AlGaN valence band end energy is decreased.

Meanwhile, on an interface between the contact well layer 317w and the contact barrier layer 317b, interface layers sometimes form mixed crystal. In such a case, average Al component of the contact well layer 316w is further increased, thereby decreasing the number of energy levels.

Therefore, it is preferable to form each contact well layer 317w to have a thickness in a range from 20 Å to 60 Å. In the first embodiment, each contact well layer 317w has a thickness of 40 Å.

In order to produce the tunnel effect, each of the first contact barrier layer 317b1 to the third contact barrier layer 317b3 should be thin having a thickness equal to or less than approximately a wavelength of a wave function of the holes, namely, 80 Å or less.

On the contrary, if the first contact barrier layer 116b1 to the third contact barrier layer 116b3 are too thin, combination of quantum levels between the contact well layers is firm to form miniband.

In the above situation, the energy levels of holes formed in each of the contact well layer 317w1 to 317w3 are split. Thereby, a probability of holes existing in a low energy state in the contact well layers is increased. Therefore, when holes are conducted from the third contact well layer 317w3 to the second cladding layer 316, a ratio of holes blocked by a large hetero barrier is still increased. As a result, an effect of decreasing an operating voltage is reduced.

Therefore, in order to keep a high tunnel probability and to prevent miniband from being forming caused by combination of quantum levels of holes between the contact well layers, it is preferable that each contact barrier layer 317b has a thickness in a range from 20 Å to 80 Å. In the third embodiment, each contact barrier layer 317b has a thickness of 60 Å.

As described above, also in the nitride semiconductor layer, between the contact layer 318 made of p-type GaN and the second cladding layer 316 made of p-type AlGaN, there is the quantum well hetero barrier layer 317 including contact well layers 317w each having bandgap energy increased further as the layer is closer to the second cladding layer 316. With the structure, even in application of a low bias voltage, holes can be efficiently conducted from the p-type contact layer 318 to the p-type second cladding layer 316.

It should also be noted that Al component and bandgap energy of each contact well layer 317w may be gradually increased (higher) and a thickness of each contact well layer 317w may be gradually smaller, as the layer is closer to the second cladding layer 316. More specifically, the contact well layers 317w have thicknesses of 60 Å, 40 Å, and 20 Å and Al component of 0.025, 0.05, and 0.075 in an order of being closer to the contact layer 318. Thereby, it is possible that energy of holes in the contact well layers 317w approaches AlGaN valence band end energy more as the contact well layer is closer to the second cladding layer 316. Furthermore, the semiconductor laser device 300 according to the third embodiment can decrease the number of energy levels of holes.

As a result, it is possible that the holes injected from the contact layer 318 efficiently exist at an energy level that is the closet to the AlGaN valence band end energy in the third contact well layer 317w3, which further decreases an operating voltage.

It should also be noted in the semiconductor laser device 300 according to the third embodiment of the present invention as described above that an example of material of the p-type second cladding layer 316 is AlGaN only, but the contact well layers 317w and the contact barrier layers 317b as well as the second cladding layer can be made of AlGaInN. With this structure, even if the contact well layers 317w is made of AlGaInN material having bandgap energy lower than bandgap energy of the p-type second cladding layer, and each of the contact barrier layers 317b is made of AlGaInN material having bandgap energy that is equal to or less than bandgap energy of the second cladding layer and is higher than bandgap energy of the contact well layers 317w, it is possible to produce the same effects as described above.

Moreover, in the semiconductor laser devices according to the first and third embodiments, by setting components to cause extensional strain in the contact barrier layers, it is possible to increase bandgap energy of the contact barrier layers. Thereby, it is possible to increase a magnitude of energy at an energy level formed in the contact well layers. Therefore, regarding a potential barrier (hetero spike) on an interface between the contact barrier layer and the intermediate layer (or the second cladding layer), it is possible to pass holes through the potential barrier even in application of a lower bias voltage, which further decreases an operating voltage. For example, by setting a lattice constant of the contact barrier layers to be smaller than a lattice constant of the semiconductor substrate, it is possible to cause extensional strain in the contact barrier layers. In addition, by setting a lattice constant of the contact barrier layers to be smaller than a lattice constant of the second cladding layer, it is also possible to cause extensional strain in the contact barrier layers.

It should also be noted that it has been described in the semiconductor laser devices according to the first to third embodiments that layers in the quantum well hetero barrier layer and the layers above and below the quantum well hetero barrier layer are stacked in an order of a cladding layer, a contact well layer, a contact barrier layer, a contact well layer, a contact barrier layer, a contact well layer, a contact barrier layer, and a contact layer. However, the layers can be stacked in an order of a cladding layer, a contact barrier layer, a contact well layer, a contact barrier layer, a contact well layer, a contact barrier layer, a contact well layer, a contact barrier layer, and a contact layer.

It should also be noted that each of the semiconductor laser devices according to the first to third embodiments includes three contact well layers. Here, a total thickness of the quantum well hetero barrier layer is in a range not to exceed a thickness (normally 0.1 μm or less) of a layer that is formed on an interface between the cladding layer and the contact layer and in the cladding layer and has an potential barrier in a structure without the quantum well hetero barrier layer. As a result, by using effect of conducting holes through the potential barrier by tunnel effect, it is possible to decrease an operating voltage.

It should also be noted that the semiconductor light emitting device according to the present invention is not limited to the semiconductor laser device. Any other semiconductor light emitting devices such as light-emitting diodes can produce the same effects.

Those skilled in the art will be readily appreciated that various modifications and combinations of the structural elements and functions in the embodiments are possible without materially departing from the novel teachings and advantages of the present invention. Accordingly, all such modifications and combinations are intended to be included within the scope of the present invention.

### INDUSTRIAL APPLICABILITY

The semiconductor light emitting device according to the present invention is useful for semiconductor laser devices, light-emitting diodes, and the like.

What is claimed is:

1. A semiconductor light emitting device including: a first cladding layer made of a semiconductor layer having a first conductivity type; an active layer; a second cladding layer made of a semiconductor layer having a second conductivity type different from the first conductivity type; and a contact layer made of a semiconductor layer having the second conductivity type, all of which are formed above a semiconductor substrate having the first conductivity type, said semiconductor light emitting device comprising
a quantum well hetero barrier layer including a contact barrier layer having the second conductivity type and contact well layers having the second conductivity type, all of which are formed between said second cladding layer and said contact layer,
wherein said contact well layers include at least a first contact well layer and a second contact well layer, said first contact well layer being formed close to said contact layer, and said second contact well layer being formed close to said second cladding layer, and
E_{CLD2}>E_{CNT} and E_{CW1}<E_{CW2}, where bandgap energy of said second cladding layer is expressed by E_{cLD2}, bandgap energy of said contact layer is expressed by E_{CNT}, bandgap energy of said first contact well layer is expressed by E_{CW1}, and bandgap energy of said second contact well layer is expressed by E_{CW2}.

2. The semiconductor light emitting device according to claim 1,
wherein the bandgap energy of each of said contact well layers is monotonically increased in a said contact layer-to-said second cladding layer direction.

3. The semiconductor light emitting device according to claim 1,
wherein E_{CLD2}≧E_{CB}>E_{CW2}>E_{CW1}≧E_{CNT}, where bandgap energy of said contact barrier layer is expressed by E_{CB}.

4. The semiconductor light emitting device according to claim 1,
wherein a thickness of each of said contact well layers is monotonically decreased in a said contact layer-to-said second cladding layer direction.

5. The semiconductor light emitting device according to claim 1,
wherein a lattice constant of said contact barrier layer is smaller than a lattice constant of said semiconductor substrate.

6. The semiconductor light emitting device according to claim 1,
wherein a lattice constant of said contact barrier layer is smaller than a lattice constant of said second cladding layer.

7. A semiconductor light emitting device including: a first cladding layer made of AlGaInP material having a first conductivity type; an active layer; a second cladding layer made of AlGaInP material having a second conductivity type different from the first conductivity type; and a contact layer made of GaAs material having the second conductivity type, all of which are formed above a GaAs substrate having the first conductivity type, said semiconductor light emitting device comprising
a quantum well hetero barrier layer including a contact barrier layer and contact well layers, all of which are formed between said second cladding layer and said contact layer, said contact barrier layer being made of (Al_{Xbp}Ga_{1-Xbp})_{Ybp}In_{1-Ybp}P, where 0≦Xbp≦1, and 0<Ybp<1, and said contact well layers each being made of Al_{Xwp}Ga_{1-Xwp}As, where 0≦Xwp<1,
wherein said contact well layers include at least a first contact well layer and a second contact well layer, said first contact well layer being formed close to said contact layer, and said second contact well layer being formed close to said second cladding layer, and
Xwp1<Xwp2, where Al component of said first contact well layer is expressed by Xwp1 and Al component of said second contact well layer is expressed by Xwp2.

8. The semiconductor light emitting device according to claim 7,
wherein the Al component Xwp of each of said contact well layers is monotonically increased in a said contact layer-to-said second cladding layer direction.

9. The semiconductor light emitting device according to claim 7,
wherein said first contact well layer is the closest to said contact layer among said contact well layers, and has the Al component Xwp1 in a range from 0 to 0.1, and
said second contact well layer is the closest to said second cladding layer among said contact well layers, and has the Al component Xwp2 in a range from 0.2 to 0.3.

10. The semiconductor light emitting device according to claim 7,
wherein a thickness of each of said first contact well layer and said second contact well layer is in a range from 20 Å to 60 Å, and
a thickness of said contact barrier layer is in a range from 20 Å to 80 Å.

11. The semiconductor light emitting device according to claim 7,
wherein a lattice constant of said contact barrier layer is smaller than a lattice constant of said GaAs substrate.

12. A semiconductor light emitting device including: a first cladding layer made of AlGaInN material having a first conductivity type; an active layer; a second cladding layer made of AlGaInN material having a second conductivity type different from the first conductivity type; and a contact layer made of GaN material having the second conductivity type, all of which are formed above a GaN substrate having the first conductivity type, said semiconductor light emitting device comprising
a quantum well hetero barrier layer including a contact barrier layer and contact well layers, all of which are formed between said second cladding layer and said contact layer, said contact barrier layer being made of Al_{Xbn}Ga_{Ybn}In_{1-Xbn-Ybn}N, where 0≦Xbn<1, 0<Ybn≦1, and 0≦Xbn−Ybn<1, and said contact well layers each being made of Al_{Xwn}Ga_{Ywn}In_{1-Xwn-Ywn}N, where 0≦Xwn<1, 0<Ywn≦1, and 0≦1−Xwn−Ywn<1,
wherein said contact well layers include at least a first contact well layer and a second contact well layer, said first contact well layer being formed close to said contact layer, and said second contact well layer being formed close to said second cladding layer, and
wherein Xwn1<Xwn2, when Al component of said first contact well layer is expressed by Xwn1 and Al component of said second contact well layer is expressed by Xwn2.

13. The semiconductor light emitting device according to claim 12,
wherein the bandgap energy of each of said contact well layers is monotonically increased in a said contact layer-to-said second cladding layer direction.

14. The semiconductor light emitting device according to claim 12,
wherein said first contact well layer is the closest to said contact layer among said contact well layers, and has the Al component Xwn1 in a range from 0 to 0.05, and
said second contact well layer is the closest to said second cladding layer among said contact well layers, and has the Al component Xwn2 that is equal to or less than Al component of said second cladding layer.

15. The semiconductor light emitting device according to claim 12,
wherein a thickness of each of said first contact well layer and said second contact well layer is in a range from 20 Å to 60 Å, and
a thickness of said contact barrier layer is in a range from 20 Å to 80 Å.

16. The semiconductor light emitting device according to claim 12,
wherein a lattice constant of said contact barrier layer is smaller than a lattice constant of said GaN substrate.
